(19) United States
(12) Patent Application Publication
(10) Pub. No.: US 2025/0253384 A1
(43) Pub. Date: Aug. 7, 2025

(54) BATTERY MANUFACTURING SYSTEM AND BATTERY MANUFACTURING METHOD

(71) Applicant: LG ENERGY SOLUTION, LTD., Seoul (KR)

(72) Inventors: Min Kyu SIM, Daejeon (KR); Min Su KIM, Daejeon (KR); Jong Seok PARK, Daejeon (KR); Dong Yeop LEE, Daejeon (KR); Kyu Taek KANG, Daejeon (KR); Jee Yeon KOH, Daejeon (KR); Ju Ye KANG, Daejeon (KR)

(21) Appl. No.: 18/606,780

(22) Filed: Mar. 15, 2024

(30) Foreign Application Priority Data
Feb. 1, 2024 (KR) 10-2024-0016070

(51) Int. Cl. H01M 10/04; H01M 4/04; H01M 50/46

(52) U.S. Cl. CPC H01M 10/0431; H01M 4/04; H01M 10/0409; H01M 50/46

(57) ABSTRACT

Systems and methods for manufacturing a battery are disclosed. One system may include: a first cutter configured to cut a first electrode sheet into a first electrode portion having a first length, the first electrode sheet comprising a first coated portion; a second cutter configured to cut a second electrode sheet into a second electrode portion having a second length, the second electrode sheet comprising a second coated portion; a winder configured to wind the first electrode portion, the second electrode portion, and a separator to form an electrode assembly; and an identification information assigning device configured to assign identification information to the electrode assembly based on: a cut count value of the first electrode sheet and/or a cut count value of the second electrode sheet; and/or a first pattern indication of the first electrode sheet and/or a second pattern indication of the second electrode sheet.

### CROSS-REFERENCE TO RELATED APPLICATION(S)

The present application claims priority to Korean Patent Application No. 10-2024-0016070 filed on Feb. 1, 2024 in the Republic of Korea, the disclosures of which are incorporated herein by reference.

### TECHNICAL FIELD

The present disclosure relates to a battery, a battery manufacturing system, and a battery manufacturing method.

### BACKGROUND

Unlike primary batteries, secondary batteries can be charged or discharged a plurality of times. The secondary batteries are widely used as energy sources for various wireless devices such as handsets, notebook computers, cordless vacuum cleaners, and the like. Recently, the manufacturing cost per unit capacity of a secondary battery has been significantly reduced due to improvements in energy density and economies of scale, and as the traveling distance of a battery electric vehicle (BEV) increases to the same level as that of a fuel vehicle, the main use of secondary battery is shifting from a mobile device to mobility.

A secondary battery is manufactured through an electrode process, an assembly process, and an activation process. Among the above processes, the electrode process is the most critical process in determining the yield and performance of battery cells. The electrode process may include a coating process, a roll pressing process, and a slitting process. In the coating process, a surface of a current collector of an electrode may be coated with an active material and an insulating material. In the pressing process, an electrode may be pressed by pressing rolls on top of the electrode. The roll pressing process may determine the density, performance, and surface quality of the electrode. In the slitting process, an electrode may be cut into a plurality of electrodes depending on the battery cell design.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

The present disclosure is directed to providing a battery manufacturing method and battery manufacturing system with improved quality for traceability and data match in a battery manufacturing process using patterned electrodes.

Each of the aspects disclosed herein may include one or more of the features described in connection with any of the other disclosed aspects or embodiments.

In one example, a battery manufacturing system may include: a first cutter configured to cut a first electrode sheet into a first electrode portion having a first length, the first electrode sheet comprising a first coated portion and a first uncoated portion; a second cutter configured to cut a second electrode sheet into a second electrode portion having a second length, the second electrode sheet comprising a second coated portion and a second uncoated portion; a winder configured to wind the first electrode portion, the second electrode portion, and a separator between the first electrode portion and the second electrode portion to form an electrode assembly; and an identification information assigning device configured to assign identification information to the electrode assembly based on: a cut count value of the first electrode sheet and/or a cut count value of the second electrode sheet; and/or a first pattern indication of the first electrode sheet and/or a second pattern indication of the second electrode sheet.

In other aspects, the system may include one or more of the following features. The system may further include a process controller configured to control: the first cutter to cut the first electrode sheet by the first length; and the second cutter to cut the second electrode sheet by the second length. The process controller may be configured to: determine whether at least one of the first electrode portion or the second electrode portion comprises a defective portion; and upon determining the at least one of the first electrode portion or the second electrode portion comprises the defective portion: cut the defective portion; wind the defective portion with the separator to form a defective electrode assembly; and discharge the defective electrode. The system may further include: a first pattern counter configured to count one or more patterns on the first electrode sheet moving between a first electrode roll and a winder and assign the first pattern indication to the one or more patterns on the first electrode sheet; and a second pattern counter configured to count one or more patterns on the second electrode sheet moving between a second electrode roll and the winder and assign the second pattern indication to the one or more patterns on the second electrode sheet. The system may further include: a first position measuring instrument configured to acquire first coordinate data indicating one or more positions of the first electrode sheet moving between a first electrode roll and the winder; and a second position measuring instrument configured to acquire second coordinate data indicating one or more positions of the second electrode sheet moving between the second electrode roll and the winder. The system may further include: a process controller configured to perform one or more processes between a first electrode roll and the winder and between a second electrode roll and the winder, the first electrode roll comprising the first electrode sheet and the second electrode roll comprising the second electrode sheet; an identification information management server configured to execute data communication; or a combination of the process controller and the identification information management server. At least one first electrode measuring and/or inspecting instrument is provided between the first electrode roll and the winder. At least one second electrode measuring and/or inspecting instrument is provided between the second electrode roll and the winder. The system may further include a monitoring server configured to generate a first electrode roll map and a second electrode roll map. The first electrode roll map may include: first position data of the first electrode sheet moving from a first electrode roll to the winder; and first process event data acquired based on a movement of the first electrode sheet and, the first process event data being associated with the first position data. The second electrode roll map may include: second position data of the second electrode sheet moving from a second electrode roll to the winder; and second process event data acquired based on a movement of the second electrode sheet, the second process data being associated with the second position data. The monitoring server may generate monitoring data by associating the identification information of the electrode assembly with one or more of the following: 1) the first pattern indication of the first electrode sheet and/or the second pattern indication of the second electrode sheet; 2) lot identification information of the first electrode sheet and/or lot identification information of the second electrode sheet; 3) at least one of a start coordinate value and an end coordinate value of the first winding length or a start coordinate value and an end coordinate value of the second winding length; 4) data comprising information on defects of the first electrode sheet and/or the second electrode sheet or defects of the electrode assembly; 5) the first process event data associated with the first position data and/or the second process event data associated with the second position data; 6) tray identification information of a tray on which the electrode assembly is loaded; 7) data comprising a loading position of the electrode assembly in the tray; and 8) can identification information of an electrode can in which the electrode assembly is accommodated.

In one example, a method of manufacturing a battery is provided. The method may include: cutting a first electrode sheet into a first electrode portion having a first length; cutting the second electrode sheet by a second electrode portion having a second length; winding the first electrode portion, the second electrode portion, and a separator between the first electrode portion and the second electrode portion to form an electrode assembly; assigning the electrode assembly identification information based on: a cut count value of the first electrode sheet and/or a cut count value of the second electrode sheet; and/or a first pattern indication of the first electrode sheet and/or a second pattern indication of the second electrode sheet.

In other aspects, the method of manufacturing a battery may include one or more of the following features or steps. The first electrode portion may include a first electrode coated portion included in a first pattern, and the second electrode portion may include a second electrode coated portion that is included in the second pattern. The second electrode coated portion may correspond to the first electrode coated portion. The first electrode sheet may include a first electrode coated portion included in a first pattern. The second electrode sheet may include a plurality of electrode coated portions. The plurality of electrode coated portions may be in separate patterns. The second electrode sheet may include an uncoated portion located between two of the plurality of electrode coated portions. The separator may include a third length. The third length may be greater than the first length and the second length. The first pattern indication may indicate a position of the first electrode sheet moving between the first electrode roll and a winder. The second pattern indication may indicate a position of the second electrode sheet moving between the second electrode roll and the winder. The method of manufacturing a battery may further include: acquiring first coordinate data indicating positions of the first electrode sheet moving between the first electrode roll and a winder and/or second coordinate data indicating positions of the second electrode sheet moving between the second electrode roll and the winder. The first coordinate data and/or the second coordinate data may be associated with at least one of: i) the identification information of the electrode assembly; ii) the cut count value of the first electrode sheet and/or the cut count value of the second electrode sheet; or iii) the first pattern indication and/or the second pattern indication.

The first coordinate data may include at least one of a start coordinate value or an end coordinate value of the first length. The second coordinate data may include at least one of a start coordinate value or an end coordinate value of the second length. The identification information of the electrode assembly may be associated with at least one of: 1) the first pattern indication of the first electrode sheet and the second pattern indication of the second electrode sheet; 2) lot identification information of the first electrode sheet and lot identification information of the second electrode sheet; 3) at least one of a start coordinate value and an end coordinate value of the first length and a start coordinate value and an end coordinate value of the second length; 4) data regarding defects of the first electrode sheet, the second electrode sheet or the electrode assembly; 5) first process event data associated with first position data and second process event data associated with second position data; 6) tray identification information of a tray on which the electrode assembly is loaded; 7) position data of a loading position of the electrode assembly in the tray; or 8) can identification information of an electrode can in which the electrode assembly is accommodated. The method may further include: determining whether at least one of the first electrode portion or the second electrode portion comprises a defective portion; and upon determining the at least one of the first electrode portion or the second electrode portion comprises the defective portion: cutting the defective portion; winding the defective portion with the separator to form a defective electrode assembly; and discharging the defective electrode.

In one example, one or more non-transitory computer-readable media comprising instructions for manufacturing a battery, the instructions capable of being performed on a processor, may be provided. The instructions may include: cutting a first electrode sheet into a first electrode portion having a first length; cutting the second electrode sheet by a second electrode portion having a second length; winding the first electrode portion, the second electrode portion, and a separator between the first electrode portion and the second electrode portion to form an electrode assembly; and assigning identification information to the electrode assembly based on: a cut count value of the first electrode sheet and/or a cut count value of the second electrode sheet; and/or a first pattern number of the first electrode sheet and/or a second pattern number of the second electrode sheet.

In other aspects, the one or more non-transitory computer-readable media may include one or more of the following features or steps. The first electrode portion may include a first electrode coated portion included in a first pattern. The second electrode portion may include a second electrode coated portion that is included in the first pattern. The second electrode coated portion may correspond to the first electrode coated portion.

In one example, a battery may be provided. The battery may include: a housing; a first electrode comprising a first indicator, the first indicator corresponding with a first pattern of a first electrode sheet; a second electrode comprising a second indicator, the second indicator corresponding with a second pattern of a second electrode sheet; and a separator between the first electrode and the second electrode. The first electrode, the second electrode, and the separator may form an electrode assembly. The electrode assembly may be accommodated in the housing. The electrode assembly may include a third indicator. The third indicator may include identification information of the electrode assembly. The housing may include a fourth indicator, the fourth indicator corresponding with the third indicator.

In other aspects, the battery may include one or more of the following features. The first indicator may be a marking on a surface of the first electrode. The first pattern may include a coated portion and an uncoated portion of the first electrode sheet. The first electrode may include at least a portion of the coated portion of the first electrode sheet. The fourth indicator may correspond with identification information of the housing. The second pattern may include a coated portion of the second electrode sheet. The separator may include a fifth indicator. The fifth indicator may be a marking on a surface of the separator.

An exemplary battery manufacturing system of the present disclosure for solving the above problems may include a first cutter configured to, after a first electrode sheet having patterns in which coated portions and uncoated portions are repeatedly arranged is unwound from a first electrode roll, cut the first electrode sheet by a first winding length, a second cutter configured to, after a second electrode sheet having patterns in which coated portions and uncoated portions are repeatedly arranged is unwound from a second electrode roll, cut the second electrode sheet by a second winding length, a winder configured to wind the first electrode sheet of the first winding length and the second electrode sheet of the second winding length with a separator therebetween so as to manufacture an electrode assembly; and an identification information assigning device configured to assign identification information to the electrode assembly on the basis of i) and ii) below: i) a cut count value of the first electrode sheet and a cut count value of the second electrode sheet; and ii) a first pattern number of the first electrode sheet corresponding to the first winding length and a second pattern number of the second electrode sheet corresponding to the second winding length.

The system may further include a process controller configured to control the first cutter to cut the first electrode sheet by the set first winding length, and control the second cutter to cut the second electrode sheet by the set second winding length.

When one electrode sheet of the first electrode sheet of the first winding length and the second electrode sheet of the second winding length is defective, the process controller may control the first cutter, the second cutter, and the winder to cut only the defective electrode sheet and wind and discharge the cut defective electrode sheet together with the separator as a defective electrode assembly.

The system may further include a first pattern counter configured to count the patterns on the first electrode sheet moving between the first electrode roll and the winder and assign the first pattern number to the patterns, and a second pattern counter configured to count the patterns on the second electrode sheet moving between the second electrode roll and the winder and assign the second pattern number to the patterns.

The system may further include a first position measuring instrument configured to acquire first coordinate data that indicates positions of the first electrode sheet moving between the first electrode roll and the winder in succession, and a second position measuring instrument configured to acquire second coordinate data that indicates the positions of the second electrode sheet moving between the second electrode roll and the winder in succession.

The identification information assigning device may be a process controller that controls each process facility from the first and second electrode rolls to the winder, an identification information management server connected to the process controller to allow data communication, or a combination of the process controller and the identification information management server.

at least one first electrode measuring instrument and/or inspecting instrument may be provided between the first electrode roll and the winder, and at least one second electrode measuring instrument and/or inspecting instrument may be provided between the second electrode roll and the winder.

The system may further include a monitoring server configured to generate each of a first electrode roll map, which is a simulating electrode, including first position data of the first electrode sheet moving from the first electrode roll to the winder, and first process event data acquired according to movement of the first electrode sheet and associated with the first position data, and a second electrode roll map including second position data of the second electrode sheet moving from the second electrode roll to the winder, and second process event data acquired according to movement of the second electrode sheet and associated with the second position data.

The monitoring server may generate monitoring data for battery manufacturing by associating the identification information of the electrode assembly with one or more of the following: 1) the first pattern number of the first electrode sheet and the second pattern number of the second electrode sheet; 2) lot identification information of the first electrode sheet and lot identification information of the second electrode sheet; 3) the cut count value of the first electrode sheet and the cut count value of the second electrode sheet; 4) at least one of a start coordinate value and an end coordinate value of the first winding length and a start coordinate value and an end coordinate value of the second winding length; 5) data regarding defects of the first electrode sheet and the second electrode sheet or defects of the electrode assembly; 6) the first process event data associated with the first position data and the second process event data associated with the second position data; 7) tray identification information of a tray on which the electrode assembly is loaded; 8) data regarding a loading position of the electrode assembly in the tray; and 9) can identification information of an electrode can in which the electrode assembly is accommodated.

A battery manufacturing method as another aspect of the present disclosure includes: a first operation of, after a first electrode sheet having patterns in which coated portions and uncoated portions are repeatedly arranged is unwound from a first electrode roll, cutting the first electrode sheet by a first winding length, and after a second electrode sheet having patterns in which coated portions and uncoated portions are repeatedly arranged is unwound from a second electrode roll, cutting the second electrode sheet by a second winding length;
a second operation of winding the first electrode sheet of the first winding length and the second electrode sheet of the second winding length with a separator therebetween so as to manufacture an electrode assembly; and
a third operation of assigning identification information to the electrode assembly on the basis of i) and ii) below: i) a cut count value of the first electrode sheet and a cut count value of the second electrode sheet; and ii) a first pattern number of the first electrode sheet corresponding to the first winding length and a second pattern number of the second electrode sheet corresponding to the second winding length.

The first electrode sheet of the first winding length may include a first electrode coated portion included in pattern 1, and the second electrode sheet of the second winding length may include a second electrode coated portion that is included in pattern 1 and corresponds to the first electrode coated portion.

The first electrode sheet of the first winding length may include a first electrode coated portion included in pattern 1, and the second electrode sheet of the second winding length may include two second electrode coated portions each included in neighboring patterns, and an uncoated portion located between the two second electrode coated portions.

The first electrode sheet of the first winding length and the second electrode sheet of the second winding length may be wound with a separator of a third winding length therebetween so that the electrode assembly may be manufactured.

The first pattern number may intermittently indicate positions of the first electrode sheet moving between the first electrode roll and a winder that performs winding, and the second pattern number may intermittently indicate positions of the second electrode sheet moving between the second electrode roll and the winder.

The manufacturing method may further include an operation of acquiring first coordinate data that indicates positions of the first electrode sheet moving between the first electrode roll and a winder in succession, and second coordinate data that indicates positions of the second electrode sheet moving between the second electrode roll and the winder in succession, wherein the first and second coordinate data are associated with at least one of the following: i) the identification information of the electrode assembly; ii) the cut count value of the first electrode sheet and the cut count value of the second electrode sheet; and iii) the first pattern number and the second pattern number.

The first coordinate data may include at least one of a start coordinate value and an end coordinate value of the first winding length, and the second coordinate data may include at least one of a start coordinate value and an end coordinate value of the second winding length.

The identification information of the electrode assembly may be associated with one or more of the following: 1) the first pattern number of the first electrode sheet and the second pattern number of the second electrode sheet; 2) lot identification information of the first electrode sheet and lot identification information of the second electrode sheet; 3) the cut count value of the first electrode sheet and the cut count value of the second electrode sheet; 4) at least one of a start coordinate value and an end coordinate value of the first winding length and a start coordinate value and an end coordinate value of the second winding length; 5) data regarding defects of the first electrode sheet and the second electrode sheet or defects of the electrode assembly; 6) the first process event data associated with the first position data and the second process event data associated with the second position data; 7) tray identification information of a tray on which the electrode assembly is loaded; 8) data regarding a loading position of the electrode assembly in the tray; and 9) can identification information of an electrode can in which the electrode assembly is accommodated. When one electrode sheet of the first electrode sheet of the first winding length and the second electrode sheet of the second winding length is defective, only the defective electrode sheet may be cut, and the cut defective electrode sheet may be wound together with the separator and discharged as a defective electrode assembly, and identification information of the defective electrode assembly may be assigned based on a cutter count value of the defective electrode sheet and a pattern number of the defective electrode sheet.

According to the present disclosure, identification (ID) information can be assigned to an electrode assembly manufactured in a winding process. As a result, it is possible to prevent the occurrence of a gray zone in which the electrode assembly cannot be tracked between the winding process and a subsequent process of the winding process.

In particular, the identification information can be associated with position data (pattern number data, coordinate data) reflecting pattern positions of electrodes with patterns. As a result, it is possible to easily perform quality tracking of electrodes processed in a winding process and an electrode process before the winding process.

According to an exemplary embodiment of the present disclosure, identification information about an electrode assembly included in, for example, a cylindrical battery or a prismatic battery, can be acquired, and the identification information can be matched to identification information of processed products (e.g., electrodes), semi-finished products, or products before and after the winding process. As a result, it is possible to easily perform quality control and quality tracking throughout the entire battery manufacturing process.

Effects obtainable in exemplary embodiments of the present disclosure are not limited to the effects described above, and other effects that are not described can be clearly derived and understood by those skilled in the art from the following descriptions to which the exemplary embodiments of the present disclosure pertain. That is, unintended effects resulting from implementing exemplary embodiments of the present disclosure may also be derived by those skilled in the art from the exemplary embodiments of the present disclosure.

### BRIEF DESCRIPTION OF THE DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawings.

FIG. 1 illustrates a battery manufacturing system according to exemplary embodiments.

FIGS. 2A and 2B illustrate a visualized roll map and patterned electrodes.

FIG. 3 illustrates a battery manufacturing system according to exemplary embodiments.

FIG. 4 is a schematic diagram illustrating an example in which an electrode and a separator are wound at a predetermined length by a winder.

FIG. 5 is a schematic diagram illustrating another example in which an electrode and a separator are wound by a winder.

FIG. 6 shows identification information of an electrode assembly that is associated with other information.

FIG. 7 is a flowchart for describing a battery manufacturing method according to exemplary embodiments.

FIG. 8 is a flowchart for describing a battery manufacturing method according to another exemplary embodiment.

### DETAILED DESCRIPTION

Hereinafter, exemplary embodiments of the present disclosure will be described in detail with reference to the accompanying drawings. Prior to this, terms and words used in this specification and claims should not be interpreted as being limited to commonly used meanings or meanings in dictionaries and should be interpreted with meanings and concepts which are consistent with the technological scope of the present disclosure based on the principle that the inventors have appropriately defined concepts of terms in order to describe the present disclosure in the best way.

Therefore, since the embodiments described in this specification and configurations illustrated in the drawings are only exemplary embodiments and do not represent the overall technological scope of the present disclosure, it is understood that the present disclosure covers various equivalents and modifications that are substitutable at the time of filing of this application.

In addition, in the description of the present disclosure, when it is determined that detailed descriptions of related well-known configurations or functions unnecessarily obscure the gist of the present disclosure, the detailed descriptions thereof will be omitted.

Since the embodiments of the present disclosure are provided to more completely explain the present disclosure to those skilled in the art, the shapes and sizes of components in the drawings may be exaggerated, omitted, or schematically illustrated for clearer description. Therefore, the size or ratio of each component does not entirely reflect the actual size or ratio.

An embodiment or implementation described herein as “exemplary” is not to be construed as preferred or advantageous, for example, over other embodiments or implementations; rather, it is intended to reflect or indicate that the embodiment(s) is/are “example” embodiment(s). Subject matter can be embodied in a variety of different forms and, therefore, covered or claimed subject matter is intended to be construed as not being limited to any exemplary embodiments set forth herein; exemplary embodiments are provided merely to be illustrative. Likewise, a reasonably broad scope for claimed or covered subject matter is intended.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of exemplary embodiments in whole or in part.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. Both the foregoing general description and the following detailed description are exemplary and explanatory only and are not restrictive of the features, as claimed.

In this disclosure, the term “based on” means “based at least in part on.” The terms including the ordinal number such as “first”, “second” and the like, may be used to distinguish one element from another among various elements, but not intended to limit the elements by the terms. The singular forms “a,” “an,” and “the” include plural referents unless the context dictates otherwise. The term “exemplary” is used in the sense of “example” rather than “ideal.” The term “or” is meant to be inclusive and means either, any, several, or all of the listed items. The terms “comprises,” “comprising,” “includes,” “including,” or other variations thereof, are intended to cover a nonexclusive inclusion such that a process, method, or product that comprises a list of elements does not necessarily include only those elements, but may include other elements not expressly listed or inherent to such a process, method, article, or apparatus. Relative terms, such as, “substantially” and “generally,” are used to indicate a possible variation of +5% of a stated or understood value.

In addition, throughout the specification, when a portion is referred to as being “connected” or “coupled” to another portion, it is not limited to the case that they are “directly connected” or “directly coupled”, but it also includes the case where they are “indirectly connected” or “indirectly coupled” with one or more elements being arranged between them.

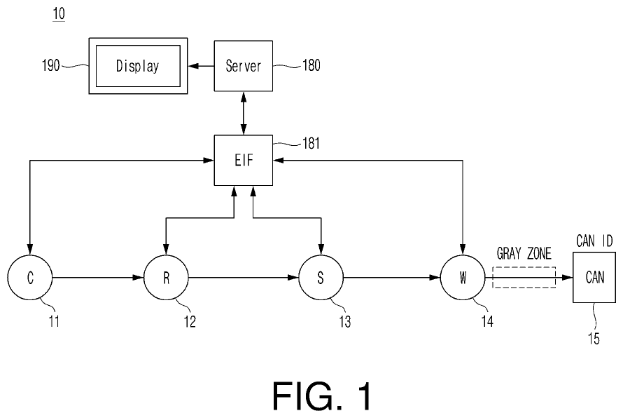

FIG. 1 illustrates a battery manufacturing system 10 according to exemplary embodiments.

Referring to FIG. 1, the battery manufacturing system 10 may include a coating device 11, a roll pressing device 12, a slitting device 13, a winding device 14, a relay server (e.g., event integration facility (EIF)) 181, a monitoring server 180, and a display device 190.

The battery manufacturing system 10 may be configured to manufacture battery cells (e.g., cylindrical battery cells, pouch-type battery cells, prismatic battery cells, etc.) by performing a series of roll-to-roll processes. An electrode sheet unwound from a provided electrode roll (not shown in the figure for clarify of illustration) may be processed by any one of a die coater of the coating device 11, pressing rolls of the roll pressing device 12, and a slitting knife of the slitting device 13, and the processed electrode sheet may be wound around the electrode roll. Accordingly, the processing of the coating device 11, the roll pressing device 12, and the slitting device 13 for production of electrodes of a battery may be referred to as a roll-to-roll process. The winding device 14 may wind a first electrode sheet (e.g., a negative electrode sheet) unwound from a first electrode roll (e.g., a negative electrode roll), a second electrode sheet (e.g., a positive electrode sheet) unwound from a second electrode roll (e.g., a positive electrode roll), and separator sheets unwound from separator rolls together.

The winding device 14 may wind the positive electrode sheet, the negative electrode sheet, and the separators interposed therebetween and separate them after reaching a winding target length to provide an electrode assembly (e.g., a jelly roll-shaped electrode assembly) of a cylindrical battery cell.

The EIF 181 may be a device for communication between process controllers of a manufacturing facility and a server system that may be located at the manufacturing facility or on a remote location. The server 180 may be coupled to the server system. For example, each process controller and the server system may be coupled to each other and may communicate directly or indirectly to and from with each other. Accordingly, process event data generated via the coating device 11, the roll pressing device 12, the slitting device 13, and the winding device 14 may be transmitted to the monitoring server 180 and/or the server system.

The monitoring server 180 may generate monitoring data for battery manufacturing. For example, the monitoring data may include a roll map including process event data. Data for the roll map may include data indicating process events and coordinate values matched with the data. The coordinate values may indicate positions of electrodes. The monitoring server 180 may transmit a visualization command to the display device 190, and the display device 190 may visualize the roll map and display the visualized roll map (VRM).

The roll map may be generated in units of lots. A lot is a production unit in a roll-to-roll process, and an electrode roll that is separated after achieving a target winding length for each process is an example of the lot. Likewise, an electrode roll loaded onto an unwinder of each process is also an example of the lot. The monitoring server 180 may generate and store a roll map of each process (e.g., coating process, roll pressing process, or slitting process).

The roll map may be a type of a simulating electrode that imitates a moving real electrode (e.g., a real electrode moving between an unwinder and a rewinder). In one embodiment, the roll map may be displayed on a display device including a two-dimensional graphical interface or a three-dimensional graphical interface. For example, the roll map may be displayed on one or more mobile or stationary display devices (e.g., computer monitor, laptop screen, touchscreen, tablet, mobile phone, etc.). Additionally or alternatively, the display device may include a wearable display device (e.g., head-mounted display) for displaying the roll map as a virtual reality or an augmented reality content on a graphical interface.

Since process events generally occur as the manufacturing process progresses, process event data related to the process events may include time series data. For example, one or more process controllers of each process (or stage) of manufacturing may control the overall flow of each process (or stage). Therefore, events that occur according to a time flow of the process or a time of data generation may be acquired. That is, data for the process events may include values indicating the events and time values matched thereto. Accordingly, the data for the process events may include time series data acquired in each process.

Further, the process event data may include equipment data acquired at each process or stage of the manufacturing facility. The equipment data may be acquired from each process controller that controls each process (or stage) of manufacturing. The process controller is a control device used for maintenance, management, automatic control, and monitoring of a process system in each process such as each of sub-processes (e.g., coating process, roll pressing process, or slitting process) of the electrode process, an assembly process (e.g., electrode stacking process or winding process), an activation process, a module/pack process, or the like. As the process controller(s), for example, one or more process programmable logic controller (PLC) may be used.

The process controller(s) may control facilities or equipment related to each process, and, for example, the driving of a motor, a motor rotation speed, etc. required to move the electrode. Alternatively, the process controller(s) may manage process parameters required for each process. As exemplary process parameters, electrode drying temperature and/or electrode temperature may be managed in the coating process, and roll pressing pressure and the like may be adjusted in the roll pressing process. Therefore, the equipment data may include various types of process parameter data managed by the process controller in each process.

Further, the process event data may include process-related measurement data and/or inspection data acquired in each process. For example, in the coating process, an electrode slurry loading amount may be measured or reference points marked on the electrode may be measured. In the roll pressing process, a thickness of the electrode after roll pressing may be measured. Further, an appearance inspecting instrument (e.g., vision inspecting instrument) or the like may be commonly used in the coating process, the roll pressing process, the slitting process, and the like. The measurement data and/or inspection data may include all inspected or measured data by a predefined measuring instrument and/or inspecting instrument in each process.

The process event data may be generated according to the progress of various processes performed on the electrode, and the process event data may be acquired for each individual process.

Still referring to FIG. 1, the electrode assembly manufactured by being wound by the winding device 14 may be transferred and accommodated in a case (or housing) such as a battery can or housing. A can (or housing) ID, which is separate can identification information, may be assigned to the can, and the can ID is a type of a battery cell ID. Therefore, historic data for the manufacture of battery cells may be retrieved based on the can ID.

However, before the electrode assembly is accommodated in the can, in terms of logistics flow, a plurality of electrode assemblies may be accommodated and stored in a tray, or the tray may be transported and transferred to the location of the can(s). When the plurality of electrode assemblies get mixed up during this process, it is difficult to determine constituent materials (electrodes, separators, etc.) of the electrode assemblies accommodated in the can even when the can ID is assigned during the can manufacturing process. That is, a gray zone in which the electrode assemblies cannot be tracked is generated between the winding process and the can manufacturing process. Accordingly, even when the roll map is generated in each sub-process before the winding process and process event data or coordinate data (CD) related to the electrode of each sub-process is secured, the corresponding data cannot be tracked in relation to the electrodes provided in the electrode assemblies in the various processes between each sub-process and the can manufacturing process.

According to the technical sprit of the present disclosure, in order to prevent the gray zone from being generated, identification information ID may be assigned to the electrode assembly manufactured during the winding process. The identification information may be assigned based on cut count values and/or pattern numbers (or pattern indicators) of electrodes included in the electrode assembly.

For example, the winding process may be a process in which an electrode and a separator are wound by a winder. Additionally or alternatively, the winding process may include all processes in which electrode sheets and separator sheets unwound from electrode rolls and separator rolls are processed and cut, and wound by a winder. That is, the unwinding process, the inspection and/or measurement process, the cutting process, and the winding process in the winder may all be included together in the winding process. In one embodiment, the roll map may be generated to imitate or simulate the electrodes moving during the winding process. As described above, the roll map may simulate a moving real electrode (e.g., a real electrode moving between an unwinder and a rewinder). In one embodiment, the roll map may be displayed on a display device including a two-dimensional graphical interface or a three-dimensional graphical interface. In one embodiment, the roll map may include various data collected during manufacturing of an electrode and/or a battery. Additionally or alternatively, the roll map may include data associated with the electrode manufacturing process in accordance with the present disclosure. For example, the data may be displayed on a display device discussed above or may be stored in one or more servers (e.g., server 180) for processing and tracking.

The roll map in the winding process may include position data indicating a position of each electrode moving during the winding process, and process event data. The identification information of the electrode assembly may be associated with the position data of the electrode, and the process event data. The position data of each electrode and the process event data that are input during the winding process may be compared with roll map data (e.g., position data and process event data) of each process generated in each sub-process prior to the winding process.

Furthermore, the identification information of the electrode assembly may be associated with data acquired in subsequent processes after the winding process (e.g., data related to the tray on which the electrode assembly is loaded, can ID, etc.). Therefore, since the data associated with each electrode assembly can be retrieved between the winding process and the subsequent process on the basis of the identification information, quality may be easily tracked between the winding process and subsequent processes. As discussed above, the data generated during the winding process may be included in the roll map to be displayed on a display or to be stored, processed, and/or tracked.

Through the identification information of the electrode assembly, all historic data related to the quality or manufacturing of the electrode may be tracked throughout the winding process and all pre- and post-processes. Accordingly, process management and quality control may be performed efficiently throughout the entire battery manufacturing process, and the battery may be more reliably manufactured.

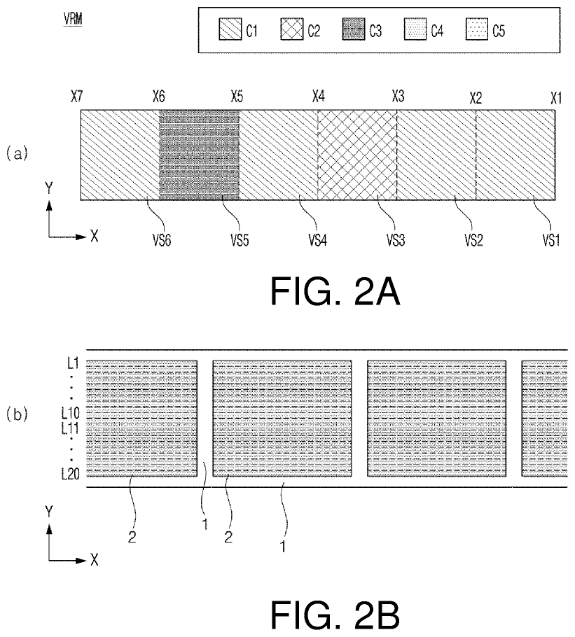

FIGS. 2A and 2B illustrate a visualized roll map and patterned electrodes, respectively.

In FIGS. 2A and 2B, arrow X indicates a longitudinal direction (e.g., traveling direction) of an electrode and/or roll map, and arrow Y indicates a width direction of the electrode and/or roll map).

A visualized roll map (VRM) in FIG. 2A may include a plurality of visualization sections VS1, VS2, VS3, VS4, VS5, and VS6 corresponding to a plurality of sections of an electrode sheet. Each of the plurality of visualization sections VS1, VS2, VS3, VS4, VS5, and VS6 may include start or beginning coordinates, end coordinates, and a color.

A representative value of coordinate-related measurement data (CMD) of the visualization sections VS1, VS2, VS4, and VS6 may be displayed in color C1, a representative value of coordinate-related measurement data (CMD) of the visualization section VS3 may be displayed in color C2, and a representative value of coordinate-related measurement data (CMD) of the visualization section VS5 may be displayed in color C3.

The color C1 may indicate that the representative value of the visualization sections VS1, VS2, VS4, and VS6 is normal or sufficient (e.g., satisfying a predetermined value or threshold), the color C2 may indicate that the representative value of the visualization section VS3 is excessive, and the color C3 may indicate that the representative value of the visualization section VS3 is very excessive. Color C4 may indicate that a representative value is insufficient, and color C5 may indicate that a representative value is very insufficient. In one embodiment, “normal or sufficient” may be defined as data that satisfies or is within one or more predetermined manufacturing tolerance characteristics or ranges of the electrode manufacturing process according to the present disclosure. Conversely, excessive or insufficient data may be defined as data that does not satisfy or is outside of one or more predetermined manufacturing tolerance characteristics or ranges of the electrode manufacturing tolerances.

In this way, since the roll map expresses the position of the electrode in coordinates and may visualize measurement data (e.g., electrode slurry loading amount data) according to each position, the efficiency of electrode production management may be improved using the roll map and the data included therein.

FIG. 2B illustrates a patterned electrode having patterns in which electrode coated portions 2 and uncoated portions 1 are repeatedly arranged.

The patterned electrode may be slit in a width direction relative to the uncoated portion 1 between the electrode coated portions 2 in the subsequent process, as shown in FIG. 2B. A slit electrode coated portion 2 may be stacked with electrode coated portions and separators of different polarity so that an electrode assembly is formed, or may be wound together with electrode coated portions and separators of different polarity so that a jelly roll-shaped electrode assembly is formed.

For example, patterned electrodes used for small batteries may be slit in a width direction and at the same time, slit in a longitudinal direction of the patterned electrode so that a plurality of electrode lanes L1 to L20 are formed, as shown in FIG. 2B.

In one embodiment, an electrode sheet may include electrode coated portions formed consecutively or contiguously in a longitudinal direction. Alternatively, an electrode sheet may include patterned electrode having electrode coated portions formed intermittently (e.g., in intervals), as shown in FIG. 2B. Therefore, the roll map method disclosed in reference to FIG. 2A, which indicates the longitudinal positions of the electrode as length coordinates in succession, which are contiguously coated, may be different from the patterned electrodes. For example, the uncoated portions of the patterned electrode may have loading amounts as measured values of 0, and are not significant portions that affect actual battery performance, and thus there is no need to display these portions in detail by linking measurement data and coordinates. Further, the patterned electrodes may be made into an electrode assembly according to the length and width of the electrode coated portions 2 constituting the pattern. That is, the electrode production result is counted as the number of electrode coated portions 2 or the number of patterns including the electrode coated portions 2. In this way, for the patterned electrode, it is necessary to assign position data according to the characteristics of the patterned electrode, in which the electrode is produced and managed and the electrode coated portions and the uncoated portions are intermittently (or in intervals) formed, on the basis of the pattern, as shown in FIG. 2B. The present disclosure provides a battery manufacturing method and battery manufacturing system that can generate monitoring data on the basis of pattern data (e.g., pattern indicators or numbers), which may be position data suitable for the patterned electrode.

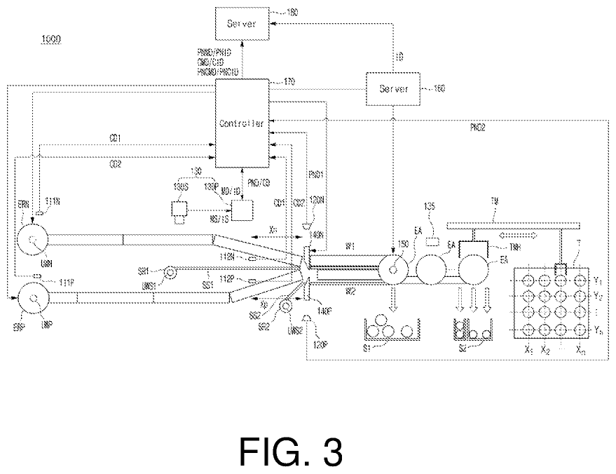

FIG. 3 illustrates a battery manufacturing system according to exemplary embodiments.

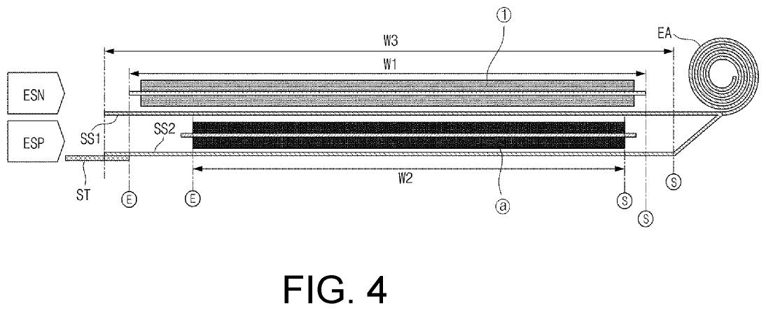

FIG. 4 is a schematic diagram illustrating an example in which an electrode and a separator are wound at a predetermined length by a winder.

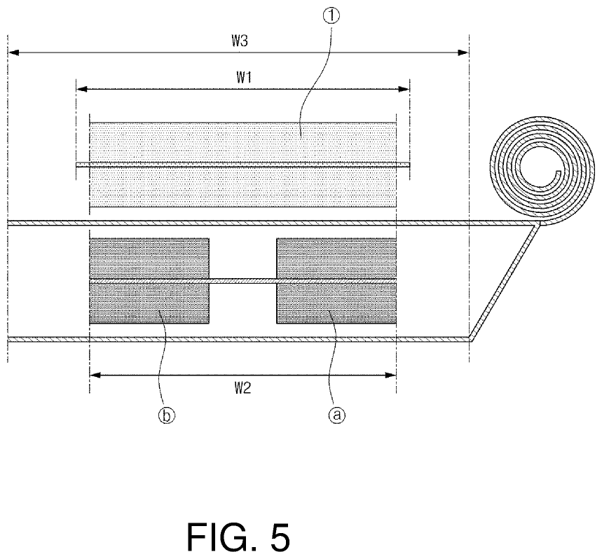

FIG. 5 is a schematic diagram illustrating another example in which an electrode and a separator are wound by a winder.

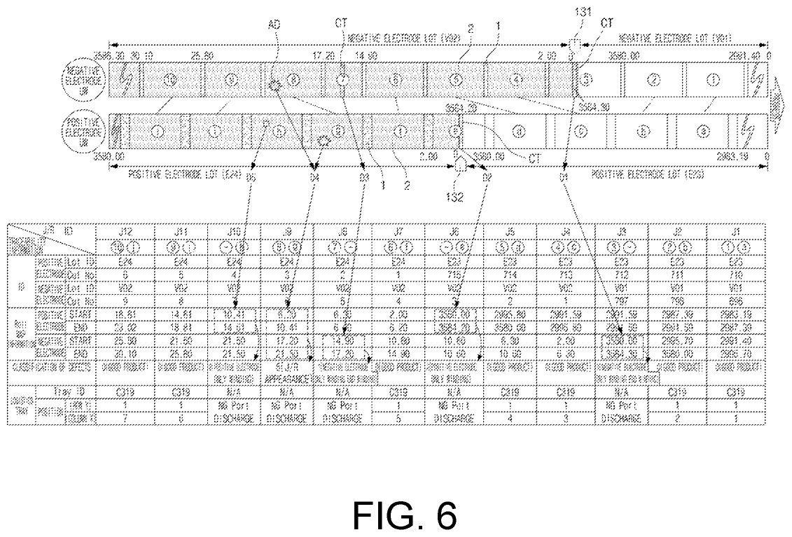

FIG. 6 shows identification information of an electrode assembly that is associated with other information.

Referring to FIG. 3, a battery manufacturing system 1000 may include unwinders UWN, UWP, UWS1, and UWS2, first position measuring instruments 111N and 112N, second position measuring instruments 111P and 112P, a first pattern counter 120N, a second pattern counter 120P, various types of measuring instrument and/or inspecting instruments 130, a first cutter 140N, a second cutter 140P, a winder 150, an identification information management server 160, a process controller 170, and a monitoring server 180.

In this specification, for convenience of description, “first” is attached to data acquired for a first electrode sheet ESN, a device related to the first electrode sheet ESN, and the like, and “second” is attached to data acquired for a second electrode sheet ESP, a device related to the second electrode sheet ESP, and the like.

A first electrode roll ERN may be loaded onto an unwinder 111N. The unwinder 111N may be configured to unwind, for example, the first electrode sheet ESN, which is a negative electrode sheet, from the first electrode roll ERN.

A second electrode roll ERP may be loaded onto an unwinder 111P. The unwinder 111P may be configured to unwind, for example, the second electrode sheet ESP, which is a positive electrode sheet, from the second electrode roll ERP.

A separator roll SR1 may be loaded onto an unwinder UWS1, and a separator roll SR2 may be loaded onto an unwinder UWS2. The unwinders UWS1 and UWS2 may be configured to unwind the separator sheets SS1 and SS2, respectively.

The first electrode sheet ESN, the second electrode sheet ESP, and the two separator sheets SS1 and SS2 may be guided by a guide roll (not illustrated in FIG. 3) and moved toward the cutters 140N and 140P and the winder 150. A plurality of guide rolls may be provided to correspond to a movement path of each sheet. Each sheet guided by each guide roll may join in front of the cutters 140N and 140P.

Each of the first electrode roll ERN and the second electrode roll ERP may be one of electrode rolls that are processed in each previous sub-process (e.g., coating process, roll pressing process, and slitting process) and then transferred to the battery manufacturing system 1000. The electrode rolls may include defective tags (NG tags) attached in the previous sub-process (e.g., roll pressing process or slitting process). Instead of the defective tag, defective parts may be marked directly on the electrode. Therefore, the electrode rolls may include defective marking portions marked on the electrode in the previous sub-process. Further, the electrode rolls may include reference points marked at predetermined intervals on the electrode in a previous sub-process (e.g., coating process). Further, the electrode rolls may include connection portions that connect electrode portions cut by fracture or defect removal during the previous sub-process, between the sub-processes, or after the sub-process. For example, connecting tape (adhesive tape) may be attached to the connection portion. By detecting positions of the reference point, the connection portion, and the defective marking portion (e.g., including defective tags) of each electrode unwound from each electrode roll by the unwinder in the winding process, it is possible to determine a change in length of each electrode sheet in the previous sub-process. The change in length may be displayed on the roll map. Roll map information for each previous sub-process may be stored in the monitoring server 180. Therefore, process control in the winding process may be efficiently performed using the roll map information for each sub-process. Further, as will be described below, events occurring in the moving electrode sheet during the winding process may be detected, and when the positions of the above-described reference point, connection portion, or defective marking portion are changed due to the above event, the positions may be displayed on the roll map of the winding process containing the process event data of the winding process. Furthermore, by comparing the roll map of the winding process with the roll map of each previous sub-process, changes in electrodes that occurred between several processes may be identified.

The first electrode sheet and the second electrode sheet are the patterned electrode sheets as illustrated in FIG. 2B.

Pattern numbers or indicators may be assigned to the patterns of each electrode sheet in order to specify the positions of the patterns on the patterned electrode sheet. One pattern may include one electrode coated portion 2 and one uncoated portion 1 consecutively from or adjacent to the coated portion. However, since a portion that functions as an actual battery is the electrode coated portion 2, the pattern number or indicator may be assigned based on each pattern of the electrode coated portion 2. Pattern number or indicator data PND1 and PND2 may be acquired by counting the pattern numbers so that the pattern number increases or decreases for each pattern of the electrode coated portion 2. Alternatively, the pattern positions may be obtained based on one or more sequences or orders of the pattern number or indicators. That is, one or more patterns of the electrode coated portion 2 may be associated with one or more pattern numbers or indicators based on the coordinate positions of the patterns of the electrode coated portions 2. A pattern number or indicator is not necessarily displayed only with Arabic numerals. When a sequence number can be displayed, the sequence number may also be displayed with the alphabet, other letters or symbols, or a combination of numbers, symbols, and letters.

In order to distinguish the positions of the patterns on the first and second electrode sheets, the pattern numbers or indicators assigned to the patterns of the first electrode sheet may be referred to as first pattern numbers or indicators, and the pattern numbers or indicators assigned to the patterns of the second electrode sheet may be referred to as second pattern numbers or indicators. Therefore, the first pattern number or indicator may intermittently (or at intervals) indicate the positions of the first electrode sheet moving between the first electrode roll and the winder. Further, the second pattern number or indicator may intermittently (or at intervals) indicate the positions of the second electrode sheet moving between the second electrode roll and the winder.

In one embodiment, the first pattern counter 120N may count patterns on the first electrode sheet ESN moving between the first electrode roll ERN and the winder 150.

The second pattern counter 120P may count patterns on the second electrode sheet ESP moving between the second electrode roll ERP and the winder 150.

The pattern counters may be installed at the same positions as the first cutter 140N and the second cutter 140P adjacent to the winder 150 or adjacent positions thereto. Therefore, when the cutters acquire the cutter count values, the pattern counters may also count the pattern numbers of the electrode sheets to be cut.

Each of the first and second pattern counters 120N and 120P may include a pitch sensor and a trigger board. The pitch sensor may measure a length of each pattern, that is, a pitch of each pattern.

According to an exemplary embodiment, the pitch sensor may be a photoelectric sensor or include a photoelectric sensor. The photoelectric sensor consists of a light emitting unit and a light receiving unit. When light emitted from the light emitting unit is blocked or reflected by an object to be detected, an amount of light reaching the light receiving unit changes. The light receiving unit detects the change, converts the change into an electrical signal, and outputs the electrical signal. The amount of light emitted from the light emitting unit reaching the light receiving unit changes based on a boundary between the electrode coated portion 2 and the uncoated portion 1 on the patterned electrode. Accordingly, the pattern counters (120N, 120P, 140N, and 140P) equipped with the pitch sensor may distinguish the electrode coated portion 2 and the uncoated portion 1 on the patterned electrode. An optical fiber sensor may be used as the photoelectric sensor. The optical fiber sensor uses an optical fiber instead of a lens of the photoelectric sensor, and since the optical fiber, which is a detection part, has no electrical part, there is an advantage of excellent environmental resistance such as noise resistance.

The pitch sensor may transmit a length of the detected pattern to the trigger board. The trigger board may generate count information for each pattern on the basis of the length of each pattern received from the pitch sensor. The trigger board may increase binary coded decimal (BCD) code by 1 whenever the count value for the length of each pattern increases. The trigger board may convert the count value for each length of the generated pattern into BCD code and transmit the BCD code to the process controller or the server.

In one embodiment, the pattern number or indicator data PND1 and PND2 and the coordinate data CD may be used together in order to indicate the longitudinal position of the electrode sheet. For example, as main position data, the pattern number or indicator data PND1 and PND2 containing the pattern numbers or indicators that intermittently (at intervals) indicate the positions of the electrode sheet may be acquired, and at the same time, the coordinate data CD containing the coordinate values that can indicate the longitudinal positions in succession may be further acquired. The coordinate values and a difference between the coordinate values may indicate the position of the electrode sheet or a distance of a specific section directly or indirectly. Therefore, by acquiring the coordinate data, it is possible to acquire more accurate position information about the electrode sheet by excluding the influence of the moving speed of the electrode sheet without performing additional calculations. By associating the coordinate data with the pattern number or indicator data PND, with the measurement data and/or the inspection data, or with the measurement data and/or inspection data associated with the pattern number data PND, status information about the electrode sheet may be acquired more accurately and reliably.

Further, based on a difference in coordinate values between start and end points of each pattern, a difference in coordinate values between start and end points of the coated portion, and a difference in coordinate values between start and end points of the uncoated portion, the length of the electrode coated portion, the length of the uncoated portion, the length of the pattern may be rapidly determined. By comparing the determined length of the pattern with the set pattern pitch, over- or under-pitched pattern may be easily identified.

The first pattern number or indicator data PND1 including first pattern numbers acquired by the first pattern counter 120N, and the second pattern number or indicator data PND2 including second pattern numbers acquired by the second pattern counter 120P may be transmitted to the process controller 170.

The first position measuring instruments 111N and 112N and the second position measuring instruments 111P and 112P may be provided to acquire coordinate data.

The first position measuring instruments 111N and 112N may acquire first coordinate data that can indicate the positions of the first electrode sheet ESN moving between the first electrode roll ERN and the winder 150 in succession.

Among the first position measuring instruments, the first position measuring instrument 111N installed at or near the unwinder UWN may be configured to detect an amount of the electrode sheet ESN unwounded from the electrode roll ERN by the unwinder. Accordingly, the first position measuring instrument 111N may be configured to generate an unwinding amount signal indicating the unwinding amount of the electrode sheet ESN. The first position measuring instrument 111N may convert the unwinding amount signal to directly acquire input amount data (coordinate data). Alternatively, the first position measuring instrument 111N may transmit the unwinding amount signal to the process controller 170, and the process controller 170 may convert the signal to collect the first coordinate data.

The first position measuring instrument 112N may be installed for the first cutter 140N near a guide roll where each sheet joins. The first position measuring instrument 112N may be configured to detect the amount of the first electrode sheet ESN moving to the winder 150. Accordingly, the first position measuring instrument 112N may be configured to detect the consumption amount of the first electrode sheet ESN moving to the winder 150. The first position measuring instrument 112N may convert the consumption amount to directly acquire the first coordinate data. Alternatively, the first position measuring instrument 112N may transmit the consumption amount to the process controller 170, and the process controller 170 may convert the signal to collect the coordinate data.

The second position measuring Instruments 111P and 112P may acquire second coordinate data CD2 that can indicate the positions of the second electrode sheet ESP moving between the second electrode roll ERP and the winder 150 in succession.

Among the second position measuring instruments 111P and 112P, the second position measuring instrument 111P installed at or near the unwinder UWP may acquire the second coordinate data of the second electrode sheet ESP based on the unwinding amount signal. Among the second position measuring instruments 111P and 112P, the second position measuring instrument 112P may be installed on or near the second cutter 140P may acquire the second coordinate data based on the signal of the consumption amount.

The first and second position measuring instruments (111N, 112N, 111P, and 112P) may be rotary encoders that can indicate the position signal of the electrode sheet moving according to the rotation amount of the unwinder or guide roll as an encoder value. Alternatively, the first and second position measuring instruments may be linear encoders that represent a position signal corresponding to the moving displacement of the electrode sheet as an encoder value. The encoders may be configured in contact or non-contact with the electrode sheet. The encoders may be equipped with a predetermined calculation unit to convert the encoder value into the coordinate value. Alternatively, the process controller may receive the encoder value and convert the encoder value into the coordinate value through a predetermined operation. In consideration of the load on the process controller, the encoders may directly convert the encoder value into the coordinate value.

The first electrode sheet ESN may advance a first distance Xn from the first position measuring instrument 112N installed for the first cutter 140N near the guide roll where each sheet joins toward the first cutter 140N. Therefore, the coordinate value of the first electrode sheet ESN based on the first cutter 140N may be corrected by adding the certain distance Xn to the coordinate value of the first electrode sheet ESN collected based on the sensing signal of the first position measuring instrument 112N installed on the first cutter 140N.

The second electrode sheet ESP may advance a certain distance Xp from the second position measuring instrument 112P installed on or near the second cutter 140P toward the second cutter 140P. Therefore, the coordinate value of the second electrode sheet ESP based on the second cutter 140P may be corrected by adding the certain distance Xp to the coordinate value of the second electrode sheet ESP collected based on the sensing signal of the second position measuring instrument 112P installed on the second cutter 140P.

The pattern number or indicator data of the first and second electrode sheets ESN and ENP acquired by the first and second pattern counters 120N and 120P may be directly transmitted to the monitoring server 180 or may be transmitted to the monitoring server 180 through the process controller 170.

Further, each piece of coordinate data of the first and second electrode sheets ESN and ENP acquired by the first and second position measuring instruments 111N, 111P, 112N, and 112P may be directly or indirectly transmitted to the monitoring server 180 or may be transmitted to the monitoring server 180 through the process controller 170.

Further, the pattern numbers or indicators and the coordinate values of portions of each of the electrode sheets corresponding to the pattern numbers or indicators may be associated with each other. The pattern number or indicator data and the coordinate data may be associated with each other based on the same time or time section at which each data was acquired. The association between the pattern number or indicator and the coordinate value may be performed in one of the processing unit of the measuring instrument and/or inspecting instrument, which will be described more in detail below, the process controller (e.g., 170), and the server (e.g., 180).

Further, the coordinate data and the pattern numbers or indicators associated therewith may be associated with at least one of the identification information of the electrode assembly, the cutter count value of the first electrode sheet, and/or the cutter count value of the second electrode sheet, which will be described below. In this disclosure, “and/or” is defined to include both conjunctive and disjunctive options. For example, A and/or B may be interpreted to include both “A and B” and “A or B.”

According to an exemplary embodiment, the battery manufacturing system 1000 according to the embodiment may include an additional position measuring instrument that can detect a position signal of each of the separator sheets SS1 and SS2.

The first electrode sheet ESN moved to the first cutter 140N by the guide roll may be cut by the first cutter 140N by a first winding length W1.

The second electrode sheet ESP moved to the second cutter 140P by the guide roll may be cut by the second cutter 140P by a second winding length W2.

The unwinders UWN and UWP, the guide roll, the first cutter 140N, the second cutter 140P, and the winder 150 may be controlled by the process controller 170.

The cutters 140N and 140P may include a predetermined cutting portion (e.g., a cutting blade) and a moving mechanism for the cutting portion. Further, the cutters 140N and 140P may include a sensor (e.g., photoelectric sensor) that can distinguish between the coated portion and the uncoated portion on the electrode sheet. The first cutter 140N and the second cutter 140P may include, for example, a cut counter (not illustrated) equipped with a trigger board (not illustrated) in order to calculate the cut count value. The trigger board may generate cut count information on the basis of each winding length (first winding length or second winding length). The trigger board may increase the count value for each winding length of each electrode sheet received. The trigger board may convert the generated cut count value of each electrode sheet into the form of BCD code and transmit the BCD code to the process controller.

The first cutter 140N may cut the first electrode sheet ESN by the first winding length W1 according to an instruction of the process controller 170.

The second cutter 140P may cut the second electrode sheet ESP by the second winding length W2 according to an instruction of the process controller 170.

The process controller 170 may control the first cutter 140N to cut the first electrode sheet ESN by the first winding length W1. Further, the process controller 170 may control the second cutter 140P to cut the second electrode sheet ESP by the second winding length W2. The process controller 170 may control each cutter on the basis of information on the first winding length W1, the second winding length W2, and a third winding length W3. The process controller 170 may include information on an entire electrode sheet transfer path (e.g., distance) on which the first electrode sheet ESN unwound from the first electrode roll ERN reaches the first cutter 140N, an entire electrode sheet transfer path (e.g., distance) on which the second electrode sheet ESP unwound from the second electrode roll ERP reaches the second cutter, and a separator transfer path (e.g., distance) on which the separators unwound from each separator roll reach the cutters. For example, the process controller 170 may receive a signal or data regarding an amount (e.g., input amount) of each electrode sheet unwound or a signal or data regarding an amount (e.g., consumption amount) reaching the cutters 140N and 140P, from the first position measuring instrument and the second position measuring instrument described above. Based on the signal and the data, the process controller 170 may determine a total transport distance of each electrode sheet. Further, based on the information about each winding length and the information about the pattern length (e.g., pattern pitch), the process controller 170 may determine the number of electrode sheet portions corresponding to several winding lengths within the total transfer distance of each electrode sheet. Therefore, the process controller 170 may control each cutter to cut each electrode sheet by the corresponding winding length.

The cut count value of the first electrode sheet cut by the first cutter 140N and the cut count value of the second electrode sheet cut by the second cutter 140P may be transmitted to the process controller 170.

In order to inspect the first electrode sheet ESN and the second electrode sheet ENP, one or more first electrode measuring instruments and/or inspecting instruments may be provided between the first electrode roll and the winder, and one or more second electrode measuring instruments and/or inspecting instruments may be provided between the second electrode roll and the winder.

For convenience of description, although only one measuring instrument and/or inspecting instrument 130 is illustrated in FIG. 3, the measuring instrument and/or inspecting instrument may be provided for each electrode sheet.

According to exemplary embodiments, the measuring instrument and/or inspecting instrument 130 may be a reference point measuring instrument for measuring the position of the reference point marked on each electrode sheet. Alternatively, the measuring instrument and/or inspecting instrument 130 may be an appearance inspecting instrument (e.g., a vision inspecting instrument) for inspecting defects on each electrode sheet. Alternatively, the measuring instrument and/or inspecting instrument 130 may be a seam sensor 131 for detecting the connecting tape on each electrode sheet. The measuring instrument and/or inspecting instrument 130 is not limited to the types described above.

Each measuring instrument and/or inspecting instrument 130 may include a sensing unit 130S and a processing unit 130P. The sensing unit 130S and the processing unit 130P may be connected in a wired or wireless manner.

The sensing unit 130S may include an imaging device such as a time delay and integration (TDI) camera, a complementary metal oxide semiconductor (CMOS) image sensor, etc. The sensing unit 130S may be configured to generate an inspection signal IS indicating a surface of each of the electrode sheets ESN and ESP or a measurement signal MS measuring the size or width, etc. The sensing unit 130S may transmit the inspection signal IS or the measurement signal MS to the processing unit 130B.

The processing unit 130P may be configured to determine a determination value indicating whether the electrode sheets ESP and ESN are defective on the basis of the inspection signal IS and/or the measurement signal MS. The processing unit 130B may be configured to generate determination values of the electrode sheets ESP and ESN by processing the inspection signal IS and/or the measurement signal MS using a set algorithm.

The processing unit 130P may be configured to collect location-related measurement data and/or inspection data on the basis of the inspection signal IS and/or the measurement signal MS, the position data (pattern number or indicator data PND and/or coordinate data CD). For example, the processing unit 130P may collect measurement data and/or inspection data PNMD/PNID associated with the pattern number or indicator data. In this case, the pattern number or indicator data PND1 and PND2 may be transmitted from the first and second pattern counters to the processing unit 130P directly or through the process controller 170.

For example, the processing unit 130P may collect measurement data and/or inspection data CMD/CID associated with the coordinate data. In this case, the coordinate data CD1 and CD2 may be transmitted from the first and second position measuring instruments to the processing unit 130P directly or through the process controller 170.

For example, the processing unit 130P may collect measurement data and/or inspection data PNCMD/PNCID associated with the pattern number or indicator data and/or the coordinate data. In this case, the pattern number or indicator data, the coordinate data, and/or the measurement data and/or the inspection data may be associated with each other based on the same time or time section.

The processing unit 130P may transmit the measurement data and/or the inspection data associated with the position data (pattern number or indicator data PND and/or coordinate data CD) to the server 180 directly or through the process controller 170.

Each cut portion of the first electrode sheet ESN of the first winding length W1 may move to the winder 150 together with the separator sheet SS1. Further, each cut portion of the second electrode sheet ESP of the second winding length W2 may move to the winder 150 together with the separator sheet SS2. Each separator sheet may move to the winder 150 without being cut in advance so as to support the moving electrode sheet.

The winder 150 may be configured to wind the first electrode sheet ESN, the separator sheet SS1, the second electrode sheet ESP, and the separator sheet SS2 together. Accordingly, an electrode assembly EA of a battery (e.g., a cylindrical cell) may be provided. The electrode assembly EA may include a winding structure of a first electrode sheet ESN, a separator sheet SS1, a second electrode sheet ESP, and a separator sheet SS2. The first electrode sheet ESN and the second electrode sheet ESP may be electrically isolated by the separator sheets SS1 and SS2. Accordingly, despite the winding of each sheet, a short circuit of the first electrode sheet ESN and the second electrode sheet ESP may be prevented. The separator sheets may be cut by a separator cutter (not illustrated for clarity of illustration and explanation) after winding.

In one embodiment, the first electrode sheet ESN and the second electrode sheet ESP are described as being first cut and being wound with the separator sheets.

Alternatively, after winding each electrode sheet and separator, a connecting portion may be cut between an end of the wound electrode assembly and each electrode sheet, and may cut a connecting portion between the end and the separator. In this case, after the separator sheet SS2, the second electrode sheet ESP, the separator sheet SS1, and the first electrode sheet ESN each may reach a target winding length, the corresponding cutter may cut the separator sheet SS2, the second electrode sheet ESP, the separator sheet SS1, and the first electrode sheet ESN for separation of the electrode assembly EA.

The manufactured electrode assembly EA may be discharged to the outside of the electrode assembly manufacturing part. The discharged electrode assembly EA may be inspected by a separate inspecting instrument 135 and then transferred to a tray T by a predetermined transfer device™. The electrode assembly EA determined to be defective by the inspecting instrument 135 may be discharged to a defect storage port S2 and stored.

Additionally or alternatively, the electrode assembly EA determined to be normal may be stored in a storage port S1. The electrode assembly EA of the storage port S1 may be gripped by, for example, a gripper TMH of the transfer device™, and transferred to the tray T in accordance with the logistics transport schedule. The tray T includes storage positions of a plurality of electrode assemblies EA. Each electrode assembly EA may be stored at a specific position within the tray T, for example, sequentially according to a transfer order or according to a separate loading algorithm. For example, when a plurality of rows X1, X2, . . . , Xn and columns Y1, Y2, . . . , Yn are present within the tray T, a tray loading position of the electrode assembly EA may be specified by ordered pairs of a matrix indicated by intersection of the rows and columns.

The electrode rolls ERN and ERP loaded onto an unwinder constitute a lot. When loading each electrode roll onto the unwinder, identification information (e.g. lot number) of each lot may be read by a predetermined reader (e.g. BCR reader). Alternatively, the lot identification information of the corresponding electrode roll may be input into a facility or system through manual input by operators. Alternatively, code indicating the lot identification information may be included in a reference point, defect marking, or the like on the electrode. Alternatively, when the seam sensor 131, which is one of measuring instruments disposed on movement paths of the first and second electrode sheets, detects connecting tape CT, lot numbers of the first electrode roll and the second electrode roll may be updated based on a detection signal. Accordingly, coordinate values of the first electrode sheet ESN and coordinate values of the second electrode sheet ESP may be reset based on a seam detection signal.

Accordingly, the lot identification information of the first electrode sheet ESN and the lot identification information of the second electrode sheet ESP input in the winding process may be identified. Further, past manufacturing historic information, for example, roll map information, of the first and second electrode sheets (ESN, ESP) may be identified based on the lot identification information.

For example, since the completed electrode assembly EA is loaded onto the tray as described above, the identification information (e.g., tray ID) of the tray T to be loaded may be associated with the corresponding electrode assembly EA to be loaded. Further, the loading position of the corresponding electrode assembly on the tray may be identified.

However, as described above, in terms of logistics flow, when a plurality of electrode assemblies EA may be mixed up in the process of being accommodated in the tray, it is not possible to determine what material (electrode, separator, etc.) the electrode assembly EA accommodated in the can is made of even when the can ID is assigned during the can manufacturing process. For this reason, even when there is the manufacturing historic information such as the roll map information for the electrode in each sub-process before the winding process, it becomes difficult to associate with the manufacturing historic information of the electrode included in the electrode assembly EA loaded onto the tray T or the can.

In order to prevent the above difficulty, the battery manufacturing system 1000 of the present disclosure includes an identification information assigning device for assigning identification information to an electrode assembly EA.

The identification information of the electrode assembly EA needs to be associated with information that can specify an electrode included in the corresponding electrode assembly EA. In the winding process, a plurality of electrode sheet portions are cut and wound. Therefore, the identification information of the electrode assembly EA may be assigned based on information that can specify a portion of the second electrode sheet of the second winding length W2 and a portion of the second electrode sheet of the second winding length W2.

According to an exemplary embodiment, the identification information of the electrode assembly EA may be assigned based on i) and ii) below,
the cut count value of the first electrode sheet and the cut count value of the second electrode sheet, and
the first pattern number or indicator of the first electrode sheet corresponding to the first winding length and/or the second pattern number in dictation of the second electrode sheet corresponding to the second winding length.

The cut count value of the first electrode sheet and the cut count value of the second electrode sheet may be acquired by the first cutter 140N and the second cutter 140P.

The first pattern number or indicator of the first electrode sheet corresponding to the first winding length and/or the second pattern number or indicator of the second electrode sheet corresponding to the second winding length may be acquired by the first pattern counter 120N and the second pattern counter 120P.

The process controller 170 may assign the identification information ID of the wound electrode assembly EA on the basis of the received cut count value of the first electrode sheet ESN, the received cut count value of the second electrode sheet ESP, the first pattern number or indicator of the first electrode sheet corresponding to the first winding length, and/or the second pattern number indicator of the second electrode sheet corresponding to the second winding length. That is, for example, when a specific portion of the first electrode sheet ESN is cut to have the first winding length W1, in this case, a cut order is counted as a specific cut count value, and/or a specific pattern number or indicator of the pattern(s) included in the specific portion of the first electrode sheet ESN may be counted or assigned as a first pattern number or indicator, a specific identification information ID may be assigned to the wound electrode assembly EA including the first electrode sheet ESN of the specific portion.

In this way, when a specific portion of the second electrode sheet ESP is cut to have the second winding length W2, a cut order may be counted as a specific cut count value, and a specific pattern number or indicator of pattern(s) included in the specific portion of the second electrode sheet ESP may be counted or assigned as a second pattern number or indicator, specific identification information ID may be assigned to the wound electrode assembly EA including the second electrode sheet ESN of the specific portion.

In some embodiments, an electrode prepared from the first electrode sheet ESN and an electrode prepared from the second electrode sheet ESP for forming an electrode assembly in accordance with the present disclosure may be assigned identification information. For example, a pattern number or indicator and/or a cut-count value associated with the first electrode sheet ESN in accordance with embodiments of the present disclosure may be assigned to the electrode from the first electrode sheet ESN. In one embodiment, the assigned ID may be a virtual ID or a physical ID. A physical ID may be provided as a marking on the electrode if sufficient space (e.g., a uncoated portion) is provided on the electrode. Similarly, pattern number or indicator and/or a cut-count value associated with the second electrode sheet ESP in accordance with embodiments of the present disclosure may be assigned to the electrode from the second electrode sheet ESP. In one embodiment, the assigned ID may be a virtual ID or a physical ID. A physical ID may be provided as a marking on the electrode if sufficient space (e.g., a uncoated portion) is provided on the electrode.

In some embodiments, a separator provided for forming an electrode assembly in accordance with the present disclosure may be assigned identification information. For example, a coordinate value and/or a cut-count value associated with the separator in accordance with embodiments of the present disclosure may be assigned to the separator. In one embodiment, the assigned ID may be a virtual ID or a physical ID. A physical ID may be provided as a marking on the separator if sufficient space (e.g., a uncoated portion) is provided on the electrode.

In one embodiment, an ID of the electrode assembly EA may be assigned by physically marking on the electrode assembly. Alternatively, the ID of the electrode assembly EA may be a virtual ID in which the process controller 170 virtually assigns identification information to the corresponding electrode assembly EA.

Since the process controller 170 is capable of performing data communication with the first and second cutters 140N and 140P and the first and second ID counters 120N and 120P, the process controller 170 may assign an ID to the electrode assembly EA on the basis of the cut count values and first and second pattern numbers or indicators of the first and second electrode sheets described above. That is, the process controller 170 may be an identification information assigning device.

Additionally, the process controller 170 may be for controlling the unwinder, the cutter, the winder, and the like. Therefore, when an operation for assigning the ID of the electrode assembly EA or an ID issuing function is provided to the process controller 170, an overload may be applied to the process controller 170. In this case, there is the risk that a control speed of the process controller 170 may become slow. In order to prevent the risk, a dedicated server for assigning and managing identification information may be added. Referring to FIG. 3, an identification information management server 160 connected to the process controller 170 to allow data communication may be provided. The identification information management server 160 may be, for example, an edge computer system (ECS) and/or an equipment data collection (EDC) server.

The identification information management server 160 may receive the cut count values and pattern numbers or indicators of the first and second electrode sheets from the process controller 170 and issue a virtual ID to the corresponding electrode assembly EA. In this case, the identification information assigning device for the electrode assembly may be the identification information management server 160.

Alternatively, the combination of the process controller 170 and the identification information management server 160 may be viewed as the identification information assigning device.

The process controller 170 and/or the identification information management server 160, or the monitoring server 180 which will be described below may further associate coordinate data in addition to the identification information, the cutter count value, and the pattern number (data). For example, the coordinate value (at least one of the start coordinate value and the end coordinate value of the first winding length) corresponding to the first winding length of the first electrode sheet acquired from the first position measuring instruments 111N and 112N, which are rotary encoders, and the coordinate value (at least one of the start coordinate value and the end coordinate value of the second winding length) corresponding to the second winding length of the second electrode sheet acquired from the second position measuring instruments 111P and 112P may be associated with the cutter count value and the pattern number or indicator (e.g., data) acquired at the same time as the coordinate value acquisition time, and accordingly, the coordinate values may also be associated with the identification information of the electrode assembly.

Accordingly, the process controller 170 and/or the identification information management server 160, or the monitoring server 180 which will be described below may assign, for example, the identification information ID to the corresponding electrode assembly EA in association with or on the basis of the start coordinate value and the end coordinate value of the first winding length W1 of the first electrode sheet, and the start coordinate value and the end coordinate value of the second winding length W2 of the second electrode sheet.

In this way, when the ID of the electrode assembly EA is identified, the cutter count value and/or the position data (the pattern number or indicator, the coordinate value) of the electrodes included in the corresponding electrode assembly are specified. Based on the cutter count value and/or the position data, the manufacturing history of each sub-process before the winding process may be tracked. Further, the defect inspection, transfer, tray loading, and can storage processes of the electrode assembly may be performed based on the ID of the electrode assembly EA. Therefore, the manufacturing history may be easily tracked in the process after the winder 150 on the basis of the identification information of the electrode assembly EA.

In one embodiment, the process controller 170 and/or the identification information management server 160 may manage the identification information of the electrode assembly EA in association with the process event data of each electrode. For example, since the measurement data and/or the inspection data acquired by various types of measuring instrument and/or inspecting instrument in the process from the unwinder to the winder is associated with the position data (pattern number data, coordinate data), the measurement data and/or the inspection data may be associated with the identification information of the electrode assembly associated with the position data through the position data

The process controller 170 may control each device provided in the winding process, and at the same time, may transmits data acquired from each device to the monitoring server 180. Further, the identification information management server 160 transmits the identification information ID assigned to the electrode assembly EA to the monitoring server 180.

The process controller 170 may transmit, for example, the measurement data and/or the inspection data PNMD/PNID associated with the pattern number or indicator, the measurement data and/or the inspection data CMD/CND associated with the coordinate data, and the measurement data and/or the inspection data PNCMD/PNCND associated with the pattern number or indicator and the coordinate data to the monitoring server 180 through the relay server such as EIF or the like. The monitoring server 180 may generate a first electrode roll map, which may include a graphical or data simulation of an electrode, including first position data (pattern number or indicator data, coordinate data) of the first electrode sheet moving from the first electrode roll to the winder, and first process event data associated with the first position data.

Further, the monitoring server 180 may generate a second electrode roll map including second position data (pattern number or indicator data, coordinate data) of the second electrode sheet moving from the second electrode roll to the winder, and second process event data associated with the second position data. The second electrode roll map may include a graphical or data simulation of an electrode.

According to exemplary embodiments, the monitoring server 180 may be a data processing system for supporting all activities required to manage battery manufacturing, such as work schedule management, work instructions, quality control, and production result calculation. The monitoring server 180 may be, for example, a manufacturing execution system (MES). The monitoring server 180 may be configured to perform input, processing, output, and communication of data required for electrode manufacturing, such as coating process, press process, and manufacturing process.

According to other exemplary embodiments, the monitoring server 180 may be configured to store and process raw measurement data. The monitoring server 180 may manage the quality of processing of the electrode sheet by continuously monitoring the processing of the electrode sheet on the basis of the measurement data. According to exemplary embodiments, the monitoring server 180 may include a statistical process controller (SPC). The monitoring server 180 may identify problem conditions in a timely manner and provide alerts to operators before potential problems occur by collecting and analyzing manufacturing data in near real time.

According to other exemplary embodiments, the monitoring server 180 may be, for example, a data warehouse and may store a roll map for a long period of time on the basis of the quality warranty period of the product.

According to other exemplary embodiments, the monitoring server 180 may perform all the functions of the MES, the SPC, and the data warehouse, or may be provided separately from the MES, the SPC, and the data warehouse to generate a roll map.

Referring to FIG. 4, it is shown that a first electrode sheet ESN of a first winding length W1 and a second electrode sheet ESP of a second winding length W2 may be wound with a separator of a third winding length W3 therebetween to form an electrode assembly EA.

For electrical safety and insulation when a jelly roll-shaped electrode assembly EA is used, the first to third winding lengths may be determined differently. For example, the winding length (e.g., third winding length W3) of the separator located between the first electrode sheet and the second electrode sheet may be made greater than the winding length of the first and second electrode sheets. In this case, the separator may be located on a radially outmost side of the jelly roll-shaped electrode assembly, and thus it is possible to prevent an electrical short circuit from occurring due to direct contact between the first and second electrode sheets. Further, for example, the winding length (e.g., first winding length W1) of the first electrode sheet, which is a negative electrode, may be made greater than the winding length (second winding length W2) of the second electrode sheet, which is a positive electrode.

Still referring to FIG. 4, the first electrode sheet of the first winding length W1 includes a first electrode coated portion included in a first pattern (e.g., first pattern number or indicator \textcircled{1}). Uncoated portions are present on both sides of the first electrode coated portion. The length acquired by summing the first electrode coated portion and the uncoated portions on both sides is set as the first winding length W1. The first winding length W1 is stored in the process controller 170 and the first cutter 140N.

The second electrode sheet of the second winding length W2 ESP may include a second electrode coated portion included in a second pattern (e.g., second pattern number or indicator \textcircled{a}). Uncoated portions are present on both sides of the second electrode coated portion. The length acquired by summing the second electrode coated portion and the uncoated portion on both sides is set as the second winding length W2. The first winding length W2 is stored in the process controller 170 and the second cutter 140P. In this way, an electrode assembly EA may be manufactured by providing one first electrode coated portion and one second electrode coated portion (one pattern each) corresponding to the first winding length W1 and the second winding length W2, respectively.

A pattern number or indicator is not necessarily displayed only with Arabic numerals. When a sequence number can be displayed, the sequence number may also be displayed with the alphabet, other letters or symbols, or a combination of numbers and letters.

In one embodiment, referring to FIG. 5, a first electrode sheet of a first winding length is the same as including a first electrode coated portion included in a first pattern (first pattern number or indicator \textcircled{1}), but a second electrode sheet of a second winding length includes two second electrode coated portions included in neighboring patterns (second pattern numbers or indicators \textcircled{a} and \textcircled{b}) and an uncoated portion located between the two second electrode coated portions. That is, in this case, one pattern number or indicator may correspond to two pattern numbers or indicators. Since the second electrode coated portions having two pattern re are provided in each ½ pattern on the second electrode sheet, the overall length of the second electrode coated portion of the second electrode sheet is approximately the same as that of pattern 1. When the electrode assembly is manufactured by winding in the pattern arrangement as illustrated in FIG. 5, there is no uncoated portion on both ends of the second electrode coated portion. Therefore, the risk of a short circuit due to contact with the current collector (uncoated portion), which may occur when the separator interposed between the two electrode sheets is damaged, may be reduced.

Further, in terms of energy density, the electrode assembly EA wound in the form illustrated in FIG. 5 may be more advantageous.

FIG. 6 shows monitoring data generated by the monitoring server 180. The monitoring server 180 may generate the monitoring data for battery manufacturing by associating the identification information of the electrode assembly with one or more of the following:
the first pattern number or indicator of the first electrode sheet and/or the second pattern number or indicator of the second electrode sheet;
lot identification information of the first electrode sheet and/or lot identification information of the second electrode sheet;
the cut count value of the first electrode sheet and/or the cut count value of the second electrode sheet;
at least one of a start coordinate value and an end coordinate value of the first winding length and a start coordinate value and an end coordinate value of the second winding length;
data regarding defects of the first electrode sheet and/or the second electrode sheet or defects of the electrode assembly;
the first process event data associated with the first position data and/or the second process event data associated with the second position data;
tray identification information of a tray on which the electrode assembly is loaded;
data regarding a loading position of the electrode assembly in the tray; and
can identification information of an electrode can in which the electrode assembly is accommodated.

The top of FIG. 6 shows roll maps of first and second electrode sheets (negative electrode sheet, positive electrode sheet) that are generated by the monitoring server 180 and move in the winding process.

First pattern numbers or indicators 1 to 10 are displayed on the roll map of the negative electrode (e.g., electrode sheet), and coordinate values are displayed at each major point. However, consecutive coordinate values (e.g., roll map coordinate values) matched to time values in the longitudinal direction of the negative electrode sheet may be stored in the monitoring server 180. Therefore, as shown in the table at the bottom of FIG. 6, the monitoring server 180 may call detailed coordinate values (e.g., start and end coordinate values of each winding length, or start and end coordinate values of each pattern) corresponding to each pattern section and perform matching (or associating) with the values. On the roll map of the negative electrode (e.g., electrode sheet), connection tape CT and appearance defects AD detected by the measuring instrument and/or inspecting instrument are also shown. The connecting tape CT may be detected by the seam sensor 131. The negative electrode sheet may not be made of one lot, but of two lots VO1 and VO2 connected with the connecting tape CT. Therefore, when the connecting tape CT is detected, the coordinate value of the electrode sheet of the second lot VO2 may be reset and may start again from 0.

Second pattern numbers or indicators \textcircled{a} to \textcircled{j}) may be displayed on the roll map of the positive electrode (sheet), and coordinate values are displayed at each major point. As shown in the table at the bottom of FIG. 6, the monitoring server 180 may call detailed coordinate values corresponding to each pattern section and perform matching (associating) with the values. On the roll map of the positive electrode (e.g., electrode sheet), connection tape CT and appearance defects AD may also be shown. The connecting tape CT may be detected by the seam sensor 132. The positive electrode sheet is made of two lots E23 and E24 connected with the connecting tape CT. Therefore, when the connecting tape CT is detected, the coordinate value of the electrode sheet of the second lot E24 may be reset and may start again from 0.

As illustrated in FIG. 6, it can be seen that J1 may be assigned as the ID of the jelly roll (J/R)-shaped electrode assembly on the basis of the pattern numbers \textcircled{1} and \textcircled{a}, the negative electrode cut count (Cut No) value of 696, and the positive electrode cut count value of 710. In this way, it can be seen that J1 to J12 are assigned as the ID of the electrode assembly on the basis of the pattern number or indicator and the cut count value of each electrode. As described above, the process controller (e.g., 170) and the identification information management server (160) may assign the IDs. The IDs of the jelly roll (J/R)-shaped electrode assembly may be virtual or physical IDs. The physical IDs may be marked on any suitable surface of the electrode assembly.

Since the lot identification information in 1) above can be acquired, for example, when each electrode roll is loaded onto the corresponding unwinder, the lot identification information may be associated with the identification information of the electrode assembly EA.

Further, with respect to the ID of the electrode assembly, start and end point coordinates of the electrode (sheet) corresponding to each pattern number may also be associated with each other as shown in the table of FIG. 6.

Further, referring to the bottom of the table in FIG. 6, a tray ID on which an electrode assembly of a specific ID may be loaded, and its loading position (row and column) may also be displayed. Information about the tray ID and information about the loading position may also be transmitted to the monitoring server 180 so that the monitoring server 180 may also associate the information with the ID of the electrode assembly. Although not shown in FIG. 6, for example, when the identification information (e.g., can ID) is assigned to the electrode can in which the electrode assembly is accommodated, the can ID may also be associated with the information. The can ID may be assigned, for example, for each tray loading position shown in FIG. 6.

FIG. 6 shows data for the electrode assembly wound so that the negative electrode and the positive electrode each correspond to one pattern (e.g., number or indicator) (e.g., see FIG. 4). Therefore, one first pattern number or indicator and one second pattern number or indicator may be associated with each other.

However, when the electrode assembly is manufactured in the form illustrated in FIG. 5, one first pattern number indicator of the negative electrode is also possible to correspond to two second pattern numbers or indicators of the positive electrode.

As shown in the roll map at the top of FIG. 6, the first process event data associated with the first position data (e.g., first pattern number or indicator, first coordinate data CD1) may be displayed on the negative electrode. For example, the connecting tape CT and appearance defect AD displayed at a specific location may also be types of process event data. In addition to defects, other measurement data and/or inspection data, such as loading amount and web thickness, may also be displayed on the roll map of the negative electrode.

In this way, the second process event data associated with the second position data (e.g., second pattern number or indicator, second coordinate data) may be displayed on the positive electrode.

Further, whether the measurement data and/or the inspection data acquired by the measuring instrument and/or inspecting instrument 130 is detective may be determined, and result values of the determination may also be acquired by the monitoring server 180 through the process controller 170. Depending on the type of the measuring instrument and/or inspecting instrument 130, the type of defect may be identified. Therefore, data regarding defects of the first electrode sheet and the second electrode sheet may be associated with the identification information of the electrode assembly EA.

Defects in the electrode sheets ESN and ESP may be identified by a defect tag or defect marking attached to an actual electrode in a sub-process (e.g., roll pressing process or slitting process) before the winding process. Alternatively, when the connecting tape connecting the broken portion is detected during the winding process, the portion of the electrode sheet provided with the connecting tape may be regarded as being defective. Alternatively, the portion determined to be defective by the measuring instrument and/or inspecting instrument within the winding process may be regarded as a defective electrode.

Meanwhile, when the electrode sheet ESN or ESP containing defects is wound with the separator sheet, the electrode sheet ESN or ESP wound with the separator sheet may become a defective electrode assembly and may be discarded into the defect storage port S2. In this case, even the wound normal electrode sheet and the separator sheet are wasted as well as the defective electrode sheet.

Therefore, when there is a defect in one of the first electrode sheet of the first winding length and the second electrode sheet of the second winding length, the process controller may control the first cutter, the second cutter, and the winder to cut only the defective electrode sheet and wind and discharge the cut defective electrode sheet together with the separator as a defective electrode assembly.

For example, when the defective electrode sheet approaches the winder 150, the process controller 170 may generate a signal to control the unwinder, guide roll, or other driving mechanism to stop unwinding of electrode sheets that do not have defects. Accordingly, only the defective electrode sheet portion may be wound by the winder 150 without winding the normal electrode sheet. Electrode assemblies of the defective electrode sheet (see J3, J6, J8, and J10 in FIG. 6) may be discharged into the defect storage port S2.

In this case, identification information J3, J6, J8, and J10 of the defective electrode assemblies may be assigned based on the cutter count value of the defective electrode sheet and the pattern number of the defective electrode sheet. That is, the ID of the defective electrode assembly is not related to the pattern number of the non-defective electrode sheet. In this case, when the cut counter of the cutter operating for the non-defective electrode sheet operates (i.e., operates without an electrode sheet), the cutter count value may be increased, and when the cut counter does not operate, the cut count value for non-defective electrode sheets may not be increased.

The process controller 170 or any controllers or processor(s) associated with the battery manufacturing systems 10 and 1000 corresponding to embodiments associated with FIGS. 1-7 may include suitable logic, circuitry, interfaces, or code that is configured to execute the instructions stored in one or more memories or any of the servers (e.g., 160, 180, 181) for carrying out some or all functions or operations of tracking, monitoring, and manufacturing electrodes, electrode assemblies, and batteries, as well as generating roll maps, in accordance with embodiments of the present disclosure. For example, The process controller 170 or any controllers or processor(s) associated with the battery manufacturing systems 10 and 1000 may include but are not limited to a processor(s), a digital signal processor(s) (DSP), a microprocessor(s), a microcontroller(s), a complex instruction set computing (CISC) processor(s), an application-specific integrated (ASIC) processor(s), a reduced instruction set (RISC) processor(s), a very long instruction word (VLIW) processor(s), a state machine, a data processing unit(s), a graphics processing unit(s) (GPU), and other processors or control circuitry. Additionally or alternatively, the process controller 170 or any controllers or processor(s) associated with the battery manufacturing systems 10 and 1000 may be located in one or more of the server system(s) described in the foregoing embodiments for carrying out some or all functions or operations of tracking, monitoring, and manufacturing electrodes, electrode assembly, and batteries, as well as generating roll maps, in accordance with embodiments of the present disclosure. The server(s) described in accordance with the present disclosure may include a physical server or a cloud server. In one embodiment, the server(s) may provide data and analysis results to the operator through various frameworks. The framework may include protocols supporting data transmission so that the display device 190 (e.g., see FIG. 1) is able to visualize data through a user interface and provide updated visualizations as new data is computed by, for example, the server 180. Protocols supporting the data transmission may use HTML, JavaScript, and/or JSON.

The roll maps may be stored in a database or any of the server(s) described in the foregoing embodiments or a separate storage medium. The database or the storage medium may be, for example, a memory. A plurality of memories may also be provided, as necessary. The memory may be a volatile memory or a non-volatile memory. As the memory of the volatile memory, a random access memory (RAM), a dynamic RAM (DRAM), a static RAM (SRAM), or the like may be used. As the memory of the non-volatile memory, a read only memory (ROM), a programmable ROM (PROM), an electrical alterable ROM (EAROM), an erasable programmable ROM (EPROM), an electrically erasable programmable ROM (EEPROM), a flash memory, or the like may be used. Examples of the above-listed memories are merely illustrative and are not limited to these examples. Alternatively, the storage medium may be a hard disk, a CD-ROM, a USB memory, a solid state drive (SSD), or the like.

The roll map and related data stored in the storage medium may be freely used in battery manufacturing, quality control, analysis, and problem tracking.

Computer-readable media having stored thereon instructions configured to cause one or more computers to perform any of the methods described herein are also described. In one embodiment, the computer-readable media may be non-transitory. A computer readable medium may include volatile or nonvolatile, removable or nonremovable media implemented in any method or technology capable of storing information, such as computer readable instructions, data structures, program modules, or other data. In general, functionality of computing devices described herein may be implemented in computing logic embodied in hardware or software instructions, which can be written in a programming language, such as C, C++, COBOL, JAVA™, PHP, Perl, Python, Ruby, HTML, CSS, Javascript, VBScript, ASPX, Microsoft.NET™ languages such as C#, and/or the like. Computing logic may be compiled into executable programs or written in interpreted programming languages. Generally, functionality described herein can be implemented as logic modules or circuitry that can be duplicated to provide greater processing capability, merged with other modules, or divided into sub modules. The computing logic can be stored in any type of computer readable medium (e.g., a non-transitory medium such as a memory or storage medium) or computer storage device and be stored on and executed by one or more general purpose or special purpose processors, thus creating a special purpose computing device configured to provide functionality described herein.

One or more aspects of FIGS. 1-7 may be incorporated into or combined with one or more aspects of the embodiments disclosed in the present disclosure. Further, detailed disclosure of the similar or identical elements already described may be omitted for brevity. However, such omissions are not disclaimers or disavowals, and except to the extent that the similar or identical elements that are already described are inconsistent with the express disclosure herein, in which case the language in the present disclosure hereinafter controls.

The applications and the functionalities disclosed in the foregoing and following embodiments may be achieved by programming the process controller 170 or any controllers or processor(s) associated with the battery manufacturing systems 10 and 1000 in accordance with the present disclosure. That is, the process controller 170 or any controllers or processor(s) associated with the battery manufacturing systems 10 and 1000 in the foregoing and following embodiments may utilize, for example, computer-readable media having stored thereon instructions configured to cause one or more computers or processors to perform any of the methods described herein.

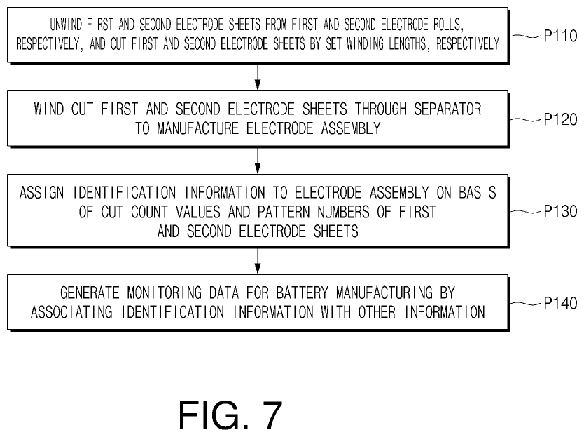

FIG. 7 is a flowchart for describing a battery manufacturing method according to exemplary embodiments.

Referring to FIGS. 3 to 7, the first electrode sheet ESN with patterns and the second electrode sheet ESP with patterns may be unwound from the first electrode roll ERN and the second electrode roll ERP, respectively, and moved toward the winder 150. Further, the separator sheet may also be unwound from the separator roll corresponding to each electrode roll and moved toward the winder 150.

The process controller 170 may move the electrode sheets and the separator sheet by operating the unwinder corresponding to each electrode roll and the separator roll.

The first electrode sheet ESN and the second electrode sheet ESP moving to the winder 150 may be inspected and measured using the predetermined measuring instrument and/or inspecting instrument. The measurement data and/or the inspection data acquired by the measuring instrument and/or inspecting instrument may be transmitted to the monitoring server 180 through the process controller 170.

Each inspected and/or measured electrode sheet may be moved by a corresponding guide roll to join the separator sheet. In this process, the first electrode sheet ESN may be cut by the first cutter 140N by the first winding length W1, and the second electrode sheet ESP may be cut by the second cutter 140P by the second winding length W2 (P110).

A portion of the first electrode sheet of the first winding length W1 and a portion of the second electrode sheet of the second winding length W2 are wound by the winder 150 through a separator to complete a jelly roll-shaped electrode assembly EA (P120). The winder 150 may include a separate cutter for cutting the separator sheet. In this case, the first electrode sheet of the first winding length and the second electrode sheet of the second winding length may be wound together with the separator of the third winding length W3 to manufacture the electrode assembly.

With respect to the completed electrode assembly EA, a predetermined identification number assigning device may assign identification information to the electrode assembly on the basis of i) and/or ii) below:
a cut count value of the first electrode sheet and/or a cut count value of the second electrode sheet; and/or
a first pattern number of the first electrode sheet corresponding to the first winding length and/or a second pattern number of the second electrode sheet corresponding to the second winding length.

The cut count values may be acquired by the cut counters provided in the cutters or the like, and the cut count values may be transmitted to the process controller 170, the identification information management server 160, or the monitoring server 180.

The pattern numbers or indicators of the first and second electrode sheets may be acquired by the first and second pattern counters. The acquired pattern numbers or indicators may be transmitted to the process controller 170, the identification information management server 160, or the monitoring server 180.

The identification information assigning device, which is the process controller 170, the identification information management server 160, or a combination thereof, may assign, for example, identification information ID to the completed electrode assembly EA on the basis of the cut count values and/or the pattern numbers or indicators (P130). The ID may be a virtual ID or a physical ID that may be provided on a surface of the electrode assembly EA.

In this case, an operation of acquiring first coordinate data CD1 that can indicate positions of the first electrode sheet moving between the first electrode roll and the winder in succession, and second coordinate data that can indicate positions of the second electrode sheet moving between the second electrode roll and the winder in succession may be further included.

The first and second coordinate data may be associated with at least one of the following:
the identification information of the electrode assembly;
the cut count value of the first electrode sheet and/or the cut count value of the second electrode sheet; and
the first pattern number or indicator and/or the second pattern number or indicator.

The first coordinate data may include at least one of a start coordinate value or an end coordinate value of the first winding length, and the second coordinate data CD2 may include at least one of a start coordinate value or an end coordinate value of the second winding length.

The identification information of the electrode assembly EA may be associated with one or more of the following by the monitoring server 180 (P140):
the first pattern number or indicator of the first electrode sheet and/or the second pattern number or indicator of the second electrode sheet;
lot identification information of the first electrode sheet and/or lot identification information of the second electrode sheet;
the cut count value of the first electrode sheet and/or the cut count value of the second electrode sheet;
at least one of the start coordinate value and the end coordinate value of the first winding length or the start coordinate value and the end coordinate value of the second winding length;
data regarding defects of the first electrode sheet and/or the second electrode sheet or defects of the electrode assembly;
the first process event data associated with the first position data and/or the second process event data associated with the second position data;
tray identification information of a tray on which the electrode assembly is loaded;
data regarding a loading position of the electrode assembly in the tray; and
can identification information of an electrode can in which the electrode assembly is accommodated.

Meanwhile, in order to save materials, when there is a defect in one of the first electrode sheet of the first winding length and the second electrode sheet of the second winding length, only the defective electrode sheet may be cut, and the cut defective electrode sheet may be wound together with the separator and discharged as a defective electrode assembly.

In this case, the identification information of the defective electrode assembly may be assigned based on the cutter count value of the defective electrode sheet and the pattern number of the defective electrode sheet.

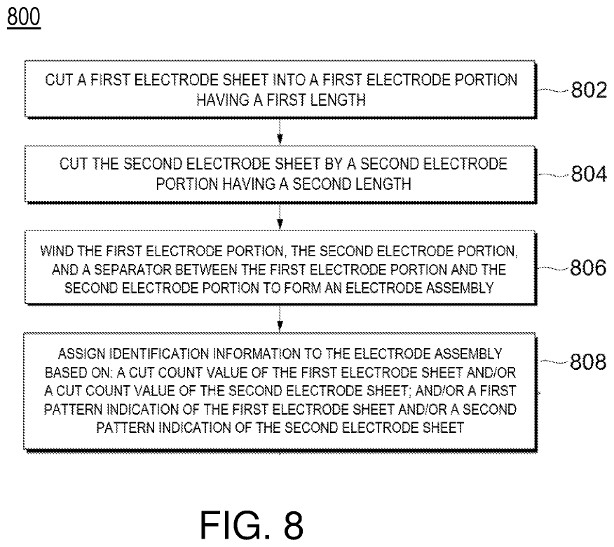

FIG. 8 depicts a flowchart of an exemplary method 800 for a method of manufacturing a battery, according to aspects of the present disclosure. For example, the method 800 may be performed according to one or more embodiments as well as one or more systems described in reference to FIGS. 1-8.

At step 802, a first electrode sheet may be cut into a first electrode portion having a first length. At step 804, the second electrode sheet may be cut by a second electrode portion having a second length. At step 806, the first electrode portion, the second electrode portion, and a separator between the first electrode portion and the second electrode portion may form an electrode assembly. At step 808, the electrode assembly may be assigned identification information based on: a cut count value of the first electrode sheet and/or a cut count value of the second electrode sheet; and/or a first pattern indication of the first electrode sheet and/or a second pattern indication of the second electrode sheet. The steps 802 to 808 are exemplary, and other alternatives can also be provided where one or more steps may be added, one or more steps may be removed, or one or more steps may be provided in a different sequence without departing from the scope of the claims herein.

In other aspects, the method of manufacturing a battery may include one or more of the following features or steps. The first electrode portion may include a first electrode coated portion included in a first pattern, and the second electrode portion may include a second electrode coated portion that is included in the second pattern. The second electrode coated portion may correspond to the first electrode coated portion. The first electrode sheet may include a first electrode coated portion included in a first pattern. The second electrode sheet may include a plurality of electrode coated portions. The plurality of electrode coated portions may be in separate patterns. The second electrode sheet may include an uncoated portion located between two of the plurality of electrode coated portions. The separator may include a third length. The third length may be greater than the first length and the second length. The first pattern indication may indicate a position of the first electrode sheet moving between the first electrode roll and a winder. The second pattern indication may indicate a position of the second electrode sheet moving between the second electrode roll and the winder. The method of manufacturing a battery may further include: acquiring first coordinate data indicating positions of the first electrode sheet moving between the first electrode roll and a winder and/or second coordinate data indicating positions of the second electrode sheet moving between the second electrode roll and the winder. The first coordinate data and/or the second coordinate data may be associated with at least one of: i) the identification information of the electrode assembly; ii) the cut count value of the first electrode sheet and/or the cut count value of the second electrode sheet; or iii) the first pattern indication and/or the second pattern indication. The first coordinate data may include at least one of a start coordinate value or an end coordinate value of the first length. The second coordinate data may include at least one of a start coordinate value or an end coordinate value of the second length. The identification information of the electrode assembly may be associated with at least one of: 1) the first pattern indication of the first electrode sheet and the second pattern indication of the second electrode sheet; 2) lot identification information of the first electrode sheet and lot identification information of the second electrode sheet; 3) at least one of a start coordinate value and an end coordinate value of the first length and a start coordinate value and an end coordinate value of the second length; 4) data regarding defects of the first electrode sheet, the second electrode sheet or the electrode assembly; 5) first process event data associated with first position data and second process event data associated with second position data; 6) tray identification information of a tray on which the electrode assembly is loaded; 7) position data of a loading position of the electrode assembly in the tray; or 8) can identification information of an electrode can in which the electrode assembly is accommodated. The method may further include: determining whether at least one of the first electrode portion or the second electrode portion comprises a defective portion; and upon determining the at least one of the first electrode portion or the second electrode portion comprises the defective portion: cutting the defective portion; winding the defective portion with the separator to form a defective electrode assembly; and discharging the defective electrode.

The systems, methods, and battery described in connection with FIGS. 1-8 of the present disclosure improve the conventional battery manufacturing, monitoring, and tracking technology. That is, the system 10, 1000, battery(s), processes, and methods of the present disclosure described herein are directed to an improvement in the field of conventional battery technology and are practically applicable to the field of battery manufacturing, monitoring, and tracking technology by utilizing the system 10, 1000, as well as the methods, processes, and functionality disclosed in connections with FIGS. 1-8 of the present disclosure. Accordingly, for example, the combined steps of the methods described in reference to FIGS. 7 and 8 improve quality for traceability and data match in a battery manufacturing process using patterned electrodes by providing the battery manufacturing system and methods in a nonconventional way. Accordingly, the manufacturing reliability of processed products, semi-finished products, and products may be improved throughout the entire battery manufacturing process.

In general, any process discussed in this disclosure that is understood to be computer-implementable, such as the processes shown in references to FIGS. 1-8 and the systems and/or interfaces described in connection with FIGS. 1-8, may be performed or otherwise implemented by one or more processors of a computer system. A process or process step performed by one or more processors may also be referred to as an operation. The one or more processors may be configured to perform such processes by having access to instructions (e.g., software or computer-readable code) that, when executed by the one or more processors, cause the one or more processors to perform the processes. The instructions may be stored in a memory of the computer system. A processor may be a central processing unit (CPU), a graphics processing unit (GPU), or another type of processing unit.

A computer apparatus or system described in reference to FIGS. 1-8, or any other system performing operation to facilitate tracking and monitoring of manufacturing data of one or more batteries and/or battery components, may include one or more computing devices. If the one or more processors of the computer system are implemented as a plurality of processors, the plurality of processors may be included in a single computing device or distributed among a plurality of computing devices. If a computer system comprises a plurality of computing devices, the memory of the computer system may include the respective memory of each computing device of the plurality of computing devices.

According to the method of the present disclosure, the quality of electrodes and an electrode assembly including the electrodes may be tracked not only within the winding process, but also between the winding process and processes before and after the winding process, through the identification information of the electrode assembly. Accordingly, the manufacturing reliability of processed products, semi-finished products, and products may be improved throughout the entire battery manufacturing process.

The present disclosure has been described above in more detail through the drawings and examples. However, since the embodiments described in this specification and configurations illustrated in drawings are only exemplary embodiments and do not represent the overall technological scope of the present disclosure, it is understood that the present disclosure covers various equivalents and modifications that are substitutable at the time of filing of this application.

### DESCRIPTION OF REFERENCE NUMERALS

10, 1000: battery manufacturing system
111N, 112N: first position measuring instrument
111P, 112P: second position measuring instrument
120N: first pattern counter
120P: second pattern counter
130: measuring instrument and/or inspecting instrument
140N: first cutter
140P: second cutter
150: winder
160: identification information management server
170: process controller
180: server

What is claimed is:

1. A battery manufacturing system comprising:
a first cutter configured to cut a first electrode sheet into a first electrode portion having a first length, the first electrode sheet comprising a first coated portion and a first uncoated portion;
a second cutter configured to cut a second electrode sheet into a second electrode portion having a second length, the second electrode sheet comprising a second coated portion and a second uncoated portion;
a winder configured to wind the first electrode portion, the second electrode portion, and a separator between the first electrode portion and the second electrode portion to form an electrode assembly; and
an identification information assigning device configured to assign identification information to the electrode assembly based on:
a cut count value of the first electrode sheet and/or a cut count value of the second electrode sheet; and/or
a first pattern indication of the first electrode sheet and/or a second pattern indication of the second electrode sheet.

2. The system of claim 1, further comprising a process controller configured to control:
the first cutter to cut the first electrode sheet by the first length; and
the second cutter to cut the second electrode sheet by the second length.

3. The system of claim 2, wherein the process controller is configured to:
determine whether at least one of the first electrode portion or the second electrode portion comprises a defective portion; and
upon determining the at least one of the first electrode portion or the second electrode portion comprises the defective portion:
cut the defective portion;
wind the defective portion with the separator to form a defective electrode assembly; and
discharge the defective electrode.

4. The system of claim 1, further comprising:
a first pattern counter configured to count one or more patterns on the first electrode sheet moving between a first electrode roll and a winder and assign the first pattern indication to the one or more patterns on the first electrode sheet; and
a second pattern counter configured to count one or more patterns on the second electrode sheet moving between a second electrode roll and the winder and assign the second pattern indication to the one or more patterns on the second electrode sheet.

5. The system of claim 1, further comprising:
a first position measuring instrument configured to acquire first coordinate data indicating one or more positions of the first electrode sheet moving between a first electrode roll and the winder; and
a second position measuring instrument configured to acquire second coordinate data indicating one or more positions of the second electrode sheet moving between the second electrode roll and the winder.

6. The system of claim 1, further comprising:
a process controller configured to perform one or more processes between a first electrode roll and the winder and between a second electrode roll and the winder, the first electrode roll comprising the first electrode sheet and the second electrode roll comprising the second electrode sheet;
an identification information management server configured to execute data communication; or
a combination of the process controller and the identification information management server.

7. The system of claim 5, wherein at least one first electrode measuring and/or inspecting instrument is provided between the first electrode roll and the winder, and
at least one second electrode measuring and/or inspecting instrument is provided between the second electrode roll and the winder.

8. The system of claim 1, further comprising a monitoring server configured to generate a first electrode roll map and a second electrode roll map,
wherein the first electrode roll map comprises:
first position data of the first electrode sheet moving from a first electrode roll to the winder; and
first process event data acquired based on a movement of the first electrode sheet and, the first process event data being associated with the first position data, and
wherein the second electrode roll map comprises:
second position data of the second electrode sheet moving from a second electrode roll to the winder; and
second process event data acquired based on a movement of the second electrode sheet, the second process data being associated with the second position data.

9. The system of claim 8, wherein the monitoring server generates monitoring data by associating the identification information of the electrode assembly with one or more of the following:
1) the first pattern indication of the first electrode sheet and/or the second pattern indication of the second electrode sheet;
2) lot identification information of the first electrode sheet and/or lot identification information of the second electrode sheet;
3) at least one of a start coordinate value and an end coordinate value of the first winding length or a start coordinate value and an end coordinate value of the second winding length;
4) data comprising information on defects of the first electrode sheet and/or the second electrode sheet or defects of the electrode assembly;
5) the first process event data associated with the first position data and/or the second process event data associated with the second position data;
6) tray identification information of a tray on which the electrode assembly is loaded;
7) data comprising a loading position of the electrode assembly in the tray; and
8) can identification information of an electrode can in which the electrode assembly is accommodated.

10. A method of manufacturing a battery comprising:
cutting a first electrode sheet into a first electrode portion having a first length;
cutting the second electrode sheet by a second electrode portion having a second length;
winding the first electrode portion, the second electrode portion, and a separator between the first electrode portion and the second electrode portion to form an electrode assembly; and
assigning identification information to the electrode assembly based on:
a cut count value of the first electrode sheet and/or a cut count value of the second electrode sheet; and/or
a first pattern indication of the first electrode sheet and/or a second pattern indication of the second electrode sheet.

11. The method of claim 10, wherein the first electrode portion comprises a first electrode coated portion included in a first pattern, and
the second electrode portion comprises a second electrode coated portion that is included in the first pattern, the second electrode coated portion corresponding to the first electrode coated portion.

12. The method of claim 10, wherein the first electrode sheet comprises a first electrode coated portion included in a first pattern,
wherein the second electrode sheet comprises a plurality of electrode coated portions, each of the plurality of electrode coated portions being in separate patterns,
wherein the second electrode sheet comprises an uncoated portion located between two of the plurality of electrode coated portions.

13. The method of claim 10, wherein the separator comprises a third length, and
wherein the third length is greater than the first length and the second length.

14. The method of claim 10, wherein the first pattern indication indicates a position of the first electrode sheet moving between the first electrode roll and a winder, and
the second pattern indication indicates a position of the second electrode sheet moving between the second electrode roll and the winder.

15. The method of claim 10, further comprising:
acquiring first coordinate data indicating positions of the first electrode sheet moving between the first electrode roll and a winder and second coordinate data indicating positions of the second electrode sheet moving between the second electrode roll and the winder,
wherein the first coordinate data and/or the second coordinate data are associated with at least one of:
i) the identification information of the electrode assembly;
ii) the cut count value of the first electrode sheet and/or the cut count value of the second electrode sheet; or
iii) the first pattern indication and/or the second pattern indication.

16. The method of claim 15, wherein the first coordinate data includes at least one of a start coordinate value or an end coordinate value of the first length, and
the second coordinate data includes at least one of a start coordinate value or an end coordinate value of the second length.

17. The method of claim 10, wherein the identification information of the electrode assembly is associated with at least one of:
1) the first pattern indication of the first electrode sheet and the second pattern indication of the second electrode sheet;
2) lot identification information of the first electrode sheet and lot identification information of the second electrode sheet;
3) at least one of a start coordinate value and an end coordinate value of the first length and a start coordinate value and an end coordinate value of the second length;
4) data regarding defects of the first electrode sheet, the second electrode sheet or the electrode assembly;
5) first process event data associated with first position data and second process event data associated with second position data;
6) tray identification information of a tray on which the electrode assembly is loaded;
7) position data of a loading position of the electrode assembly in the tray; or
8) can identification information of an electrode can in which the electrode assembly is accommodated.

18. The method of claim 10, further comprising:
determining whether at least one of the first electrode portion and the second electrode portion comprises a defective portion; and
upon determining the at least one of the first electrode portion and the second electrode portion comprises the defective portion:
cutting the defective portion;
winding the defective portion with the separator to form a defective electrode assembly; and
discharging the defective electrode.

19. One or more non-transitory computer-readable media comprising instructions for manufacturing a battery, the instructions capable of being performed on a processor, the instructions comprising:
cutting a first electrode sheet into a first electrode portion having a first length;
cutting the second electrode sheet by a second electrode portion having a second length;
winding the first electrode portion, the second electrode portion, and a separator between the first electrode portion and the second electrode portion to form an electrode assembly; and
assigning identification information to the electrode assembly based on:
a cut count value of the first electrode sheet and/or a cut count value of the second electrode sheet; and/or
a first pattern number of the first electrode sheet and/or a second pattern number of the second electrode sheet.

20. The one or more non-transitory computer-readable media of claim 19, wherein the first electrode portion comprises a first electrode coated portion included in a first pattern, and
the second electrode portion comprises a second electrode coated portion that is included in the first pattern, the second electrode coated portion corresponding to the first electrode coated portion.

21. A battery comprising:
a housing;
a first electrode comprising a first indicator, the first indicator corresponding with a first pattern of a first electrode sheet;
a second electrode comprising a second indicator, the second indicator corresponding with a second pattern of a second electrode sheet; and
a separator between the first electrode and the second electrode,
wherein the first electrode, the second electrode, and the separator form an electrode assembly, the electrode assembly being accommodated in the housing,
wherein the electrode assembly comprises a third indicator, the third indicator comprising identification information of the electrode assembly, and
wherein the housing comprises a fourth indicator, the fourth indicator corresponding with the third indicator.

22. The battery of claim 21, wherein the first indicator is a marking on a surface of the first electrode.

23. The battery of claim 21, wherein the first pattern comprises a coated portion and an uncoated portion of the first electrode sheet, and
wherein the first electrode comprises at least a portion of the coated portion of the first electrode sheet.

24. The battery of claim 21, wherein the fourth indicator corresponds with identification information of the housing.

25. The battery of claim 21, wherein the second pattern comprises a coated portion of the second electrode sheet.

26. The battery of claim 21, wherein the separator comprises a fifth indicator, and
wherein the fifth indicator is a marking on a surface of the separator.
